(19) United States
(12) Patent Application Publication
(10) Pub. No.: US 2024/0087857 A1
(43) Pub. Date: Mar. 14, 2024

(54) PLASMA PROCESSING APPARATUS AND SUBSTRATE SUPPORT

(71) Applicant: Tokyo Electron Limited, Tokyo (JP)

(72) Inventors: Chishio KOSHIMIZU, Miyagi (JP); Shoichiro MATSUYAMA, Miyagi (JP); Makoto KATO, Miyagi (JP)

(73) Assignee: Tokyo Electron Limited, Tokyo (JP)

(21) Appl. No.: 18/518,696

(22) Filed: Nov. 24, 2023

Related U.S. Application Data
(63) Continuation of application No. PCT/JP2022/020841, filed on May 19, 2022.

(30) Foreign Application Priority Data
Jun. 1, 2021 (JP) 2021-092336

(51) Int. Cl. H01J 37/32

(52) U.S. Cl. CPC H01J 37/32715; H01J 37/32568

(57) ABSTRACT

A plasma processing apparatus includes a substrate support. The substrate support includes a base, an electrostatic chuck, a chuck electrode, and an electrode structure. The electrostatic chuck is disposed on the base and has a central region and an annular region. The chuck electrode is disposed in the central region. The electrode structure is disposed below the chuck electrode in the central region and is placed in an electrically floating state. The electrode structure includes a first electrode layer, a second electrode layer disposed below the first electrode layer, and one or more connectors that connect the first electrode layer and the second electrode layer. At least one bias power supply is electrically coupled to the substrate support.

### CROSS-REFERENCE TO RELATED APPLICATIONS

This application is a bypass continuation application of international application No. PCT/JP2022/020841 having an international filing date of May 19, 2022 and designating the United States, the international application being based upon and claiming the benefit of priority from Japanese Patent Application No. 2021-092336, filed on Jun. 1, 2021, the entire contents of which are incorporated herein by reference.

### TECHNICAL FIELD

Exemplary embodiments of the present disclosure relate to a substrate support, a plasma processing apparatus, and a method of producing an electrostatic chuck.

### BACKGROUND

A plasma processing apparatus is used in plasma processing with respect to a substrate. The plasma processing apparatus includes a chamber and a substrate support. The substrate support includes a base and an electrostatic chuck and is provided in the chamber. The electrostatic chuck is located on the base. The electrostatic chuck includes a first region on which the substrate is placed, and a second region on which an edge ring is placed. The first region has a thickness larger than that of the second region. Such a plasma processing apparatus is disclosed in Patent Literature 1 described below.

### SUMMARY

In an exemplary embodiment, a plasma processing apparatus is provided. The plasma processing apparatus includes a plasma processing chamber, a substrate support, and at least one bias power supply. The substrate support is disposed in the plasma processing chamber. The substrate support includes a base, an electrostatic chuck, a chuck electrode, and an electrode structure. The electrostatic chuck is disposed on the base and has a central region with a substrate support surface and an annular region surrounding the central region. The annular region has a thickness smaller than that of the central region. The chuck electrode is disposed in the central region. The electrode structure is disposed below the chuck electrode in the central region and is placed in an electrically floating state.

In the exemplary embodiment, the electrode structure includes a first electrode layer, a second electrode layer disposed below the first electrode layer, and one or more connectors that connect the first electrode layer and the second electrode layer. The first electrode layer and the second electrode layer extend over the substrate support surface in a plan view. The at least one bias power supply is electrically connected to the substrate support.

### BRIEF DESCRIPTION OF DRAWINGS

FIG. 1 is a diagram schematically showing a plasma processing apparatus according to an exemplary embodiment.

FIG. 2 is a diagram schematically showing a plasma processing apparatus according to an exemplary embodiment.

FIG. 3 is a diagram illustrating a substrate support according to an exemplary embodiment.

FIG. 4 is a diagram illustrating a substrate support according to another exemplary embodiment.

FIG. 5 is a diagram illustrating a substrate support according to still another exemplary embodiment.

FIG. 6 is a diagram illustrating a substrate support according to still another exemplary embodiment.

FIG. 7 is a diagram illustrating a substrate support according to still another exemplary embodiment.

FIG. 8 is a diagram illustrating a substrate support according to still another exemplary embodiment.

FIG. 9 is a diagram illustrating a substrate support according to still another exemplary embodiment.

FIG. 10 is a diagram illustrating a substrate support according to still another exemplary embodiment.

FIG. 11 is a diagram illustrating a substrate support according to still another exemplary embodiment.

FIG. 12 is a diagram illustrating a substrate support according to still another exemplary embodiment.

FIG. 13 is a diagram illustrating a substrate support according to still another exemplary embodiment.

FIG. 14 is a diagram illustrating a substrate support according to still another exemplary embodiment.

FIG. 15 is a diagram illustrating a substrate support according to still another exemplary embodiment.

FIG. 16 is a diagram illustrating a substrate support according to still another exemplary embodiment.

FIG. 17 is a diagram illustrating a substrate support according to still another exemplary embodiment.

FIG. 18 is a diagram illustrating a substrate support according to still another exemplary embodiment.

FIG. 19 is a diagram illustrating a substrate support according to still another exemplary embodiment.

FIG. 20 is a diagram illustrating a substrate support according to still another exemplary embodiment.

FIG. 21 is a diagram illustrating a substrate support according to still another exemplary embodiment.

FIG. 22 is a diagram illustrating a substrate support according to still another exemplary embodiment.

FIG. 23 is a diagram illustrating a substrate support according to still another exemplary embodiment.

FIG. 24 is a diagram illustrating a substrate support according to still another exemplary embodiment.

FIG. 25 is a diagram illustrating a substrate support according to still another exemplary embodiment.

FIG. 26 is a diagram illustrating a substrate support according to still another exemplary embodiment.

FIG. 27 is a perspective view of an electrode structure as an example.

FIG. 28 is a diagram illustrating a substrate support according to still another exemplary embodiment.

### DETAILED DESCRIPTION

The inventors have developed the technology of the present disclosure which may reduce a difference between an impedance between a base and a substrate placed on a substrate support surface and an impedance between the base and an edge ring placed on the annular region in the substrate support.

Hereinafter, various exemplary embodiments will be described in detail with reference to the drawings. Further, like reference numerals will be given to like or corresponding parts throughout the drawings.

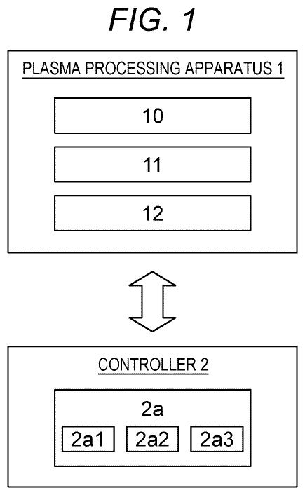

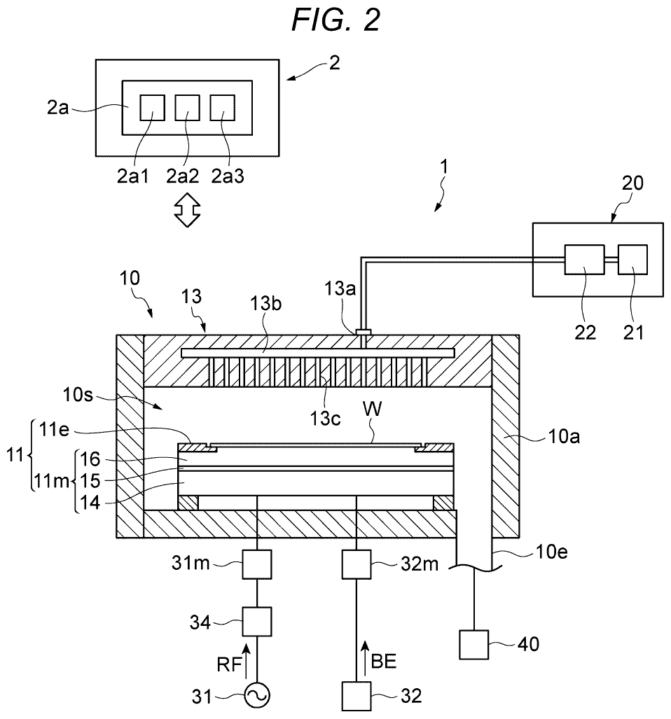

FIGS. 1 and 2 are diagrams schematically illustrating a plasma processing apparatus according to one exemplary embodiment.

In an embodiment, a plasma processing system includes a plasma processing apparatus 1 and a controller 2. The plasma processing apparatus 1 includes a plasma processing chamber 10, a substrate support 11, and a plasma generator 12. The plasma processing chamber 10 has a plasma processing space. Further, the plasma processing chamber 10 has at least one gas supply port for supplying at least one processing gas into the plasma processing space, and at least one gas exhaust port for exhausting the gas from the plasma processing space. The gas supply port is connected to a gas supply 20 which will be described later, and the gas exhaust port is connected to an exhaust system 40 which will be described later. The substrate support 11 is disposed in the plasma processing space and has a substrate support surface for supporting the substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Further, various types of plasma generators, including an alternating current (AC) plasma generator and a direct current (DC) plasma generator, may be used. In one embodiment, an AC signal (AC power) used by the AC plasma generator has a frequency in a range of 100 kHz to 10 GHz. Accordingly, the AC signal includes a radio frequency (RF) signal and a microwave signal. In one embodiment, the RF signal has a frequency in a range of 200 kHz to 150 MHz.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include, for example, a computer 2a. For example, the computer 2a may include a processor (central processing unit (CPU)) 2al, a storage 2a2, and a communication interface 2a3. The processor 2al may be configured to perform various control operations based on a program stored in the storage 2a2. The storage unit 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

Hereinafter, a configuration example of a capacitively coupled plasma processing apparatus as an example of the plasma processing apparatus 1 will be described. The capacitively coupled plasma processing apparatus 1 includes the plasma processing chamber 10, the gas supply 20, a plurality of power supplies, and the exhaust system 40. Further, the plasma processing apparatus 1 includes the substrate support 11 and a gas introduction unit. The gas introduction unit is configured to introduce at least one processing gas into the plasma processing chamber 10. The gas introduction unit includes a shower head 13. The substrate support 11 is disposed in the plasma processing chamber 10. The shower head 13 is disposed above the substrate support 11. In one embodiment, the shower head 13 constitutes at least a part of a ceiling of the plasma processing chamber 10. The plasma processing chamber 10 has a plasma processing space 10s defined by the shower head 13, a sidewall 10a of the plasma processing chamber 10, and the substrate support 11. The sidewall 10a is grounded. The shower head 13 and the substrate support 11 are electrically insulated from a housing of the plasma processing chamber 10.

The substrate support 1l includes a main body portion 11m and an edge ring 11e. The main body portion 11m is configured to support a substrate W and the edge ring 11e. The substrate support 11 may include a temperature control module configured to adjust at least one of an electrostatic chuck 16, the edge ring 11e, and the substrate W to a target temperature. The temperature control module may include a heater, a heat transfer medium, a flow path, or a combination thereof. A heat transfer fluid, such as brine or gas, flows through the flow path. Further, the substrate support 11 may include a heat transfer gas supply configured to supply a heat transfer gas to a gap between the rear surface of the substrate W and the upper surface of the substrate support 11.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 functions as an upper electrode. The gas introduction unit may include, in addition to the shower head 13, one or a plurality of side gas injectors (SGI) that are attached to one or a plurality of openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include at least one flow rate modulation device that modulates or pulses the flow rate of at least one processing gas.

The plurality of power supplies of the plasma processing apparatus 1 include a direct-current power supply used for holding the substrate W by an electrostatic attraction force, a radio-frequency power supply used for generating a plasma, and at least one bias power supply used for drawing ions from the plasma. The details of the plurality of power supplies will be described later.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

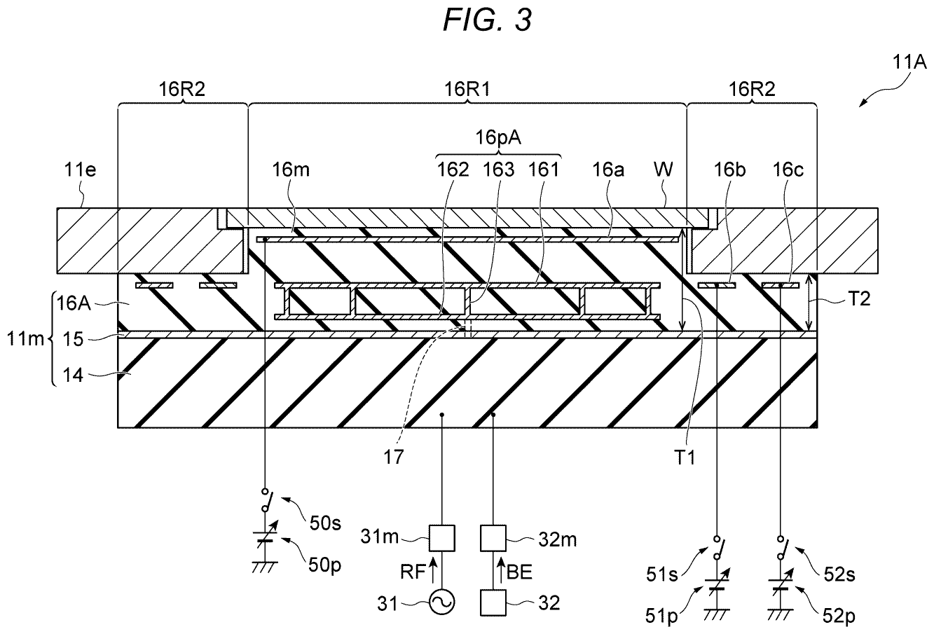

Hereinafter, in addition to FIGS. 1 and 2. FIG. 3 will be referred to. FIG. 3 is a diagram illustrating a substrate support according to an exemplary embodiment. A substrate support 11A illustrated in FIG. 3 can be used as the substrate support 11 of the plasma processing apparatus 1.

The substrate support 11A includes a base 14 and an electrostatic chuck 16A. The base 14 has a substantially disk shape. The base 14 is formed of metal such as aluminum. A radio-frequency power supply 31 (RF power supply) is electrically connected to the base 14 via a matcher 31m. Further, a bias power supply 32 is electrically connected to the base 14.

The radio-frequency power supply 31 is configured to generate radio-frequency power RF for generating plasma from the gas within the chamber 10. The radio-frequency power RF has a frequency in the range of 13 MHz or more and 150 MHz or less. The matcher 31m has a matching circuit for matching the impedance on the load of the radio-frequency power supply 31 with the output impedance of the radio-frequency power supply 31.

The bias power supply 32 is configured to generate bias energy BE for drawing ions from the plasma toward the substrate W. The bias energy BE is electric energy and has a bias frequency in the range of 100 kHz or more and 13.56 MHz or less.

The bias energy BE may be the radio frequency power having the bias frequency, that is, radio frequency bias power. In this case, the bias power supply 32 is electrically connected to the base 14 via the matcher 32m. The matcher 32m has a matching circuit for matching the impedance of the load of the bias power supply 32 with the output impedance of the bias power supply 32.

Alternatively, the bias energy BE may be a pulse, which is periodically generated, of a voltage. A time interval at which the pulse of the voltage is generated, that is, the time length of the period is the reciprocal of the bias frequency. The pulse of the voltage may have a negative polarity or a positive polarity. The pulse of the voltage may be a pulse of a negative direct-current voltage. The pulse of the voltage may have any waveform such as a rectangular wave, a triangular wave, or an impulse wave.

The electrostatic chuck 16A is provided on the base 14. The electrostatic chuck 16A is fixed to the base 14 via a bonding member 15. The bonding member 15 may be an adhesive or a brazing material. The adhesive may be an adhesive containing metal.

The electrostatic chuck 16A has a main body 16m and various electrodes. The main body 16m is formed of a dielectric, such as aluminum oxide or aluminum nitride, and has a substantially disk shape. The various electrodes of the electrostatic chuck 16A are provided in the main body 16m.

The electrostatic chuck 16A includes a first region 16R1 (central region) and a second region 16R2 (annular region). The first region 16R1 is a central region of the electrostatic chuck 16A, and includes a central part of the main body 16m. The first region 16R1 is substantially circular region in plan view. The first region 16R1 has a substrate support surface. The substrate support surface is an upper surface of the first region 16R1, and the substrate W is placed on the substrate support surface. The second region 16R2 extends in a circumferential direction around a central axis of the electrostatic chuck 16A to surround the first region 16R1. The second region 16R2 includes a peripheral part of the main body 16m. The second region 16R2 is a ring-shaped region in plan view. The second region 16R2 has an edge ring support surface. The edge ring support surface is an upper surface of the second region 16R2, and the edge ring 11e is placed on the edge ring support surface. A thickness T1 of the first region 16R1 is larger than a thickness T2 of the second region 16R2. That is, the thickness T2 of the second region 16R2 is smaller than the thickness T1 of the first region 16R1. A position of the upper surface of the first region 16R1 in a vertical direction is higher than a position of the second region 16R2 in the vertical direction.

The first region 16R1 is configured to hold the substrate W placed on the first region 16R1. The first region 16R1 includes a chuck electrode 16a. The chuck electrode 16a is a film formed of a conductive material and is provided in the main body 16m within the first region 16R1. The chuck electrode 16a may have a substantially circular planar shape. The central axis of the chuck electrode 16a may substantially coincide with the central axis of the electrostatic chuck 16A.

A direct-current power supply 50p is connected to the chuck electrode 16a via a switch 50s. When a direct-current voltage from the direct-current power supply 50p is applied to the chuck electrode 16a, an electrostatic attraction force is generated between the first region 16R1 and the substrate W. Due to the generated electrostatic attraction force, the substrate W is attracted to the first region 16R1 and held by the first region 16R1.

The second region 16R2 is configured to support the edge ring 11e placed on the second region 16R2. The substrate W is disposed on the first region 16R1 and in a region surrounded by the edge ring 11e. In one embodiment, the second region 16R2 includes chuck electrodes 16b and 16c. Each of the chuck electrodes 16b and 16c is a film formed of a conductive material and is provided in the main body 16m within the second region 16R2. Each of the chuck electrodes 16b and 16c may extend in the circumferential direction around the central axis of the electrostatic chuck 16A. The chuck electrode 16c may extend outside the chuck electrode 16b.

A direct-current power supply 51p is connected to the chuck electrode 16b via a switch 51s. A direct-current power supply 52p is connected to the chuck electrode 16c via a switch 52s. When a direct-current voltage from the direct-current power supply 51p is applied to the chuck electrode 16b and a direct-current voltage from the direct-current power supply 52p is applied to the chuck electrode 16c, an electrostatic attraction force is generated between the second region 16R2 and the edge ring 11e. Due to the generated electrostatic attraction force, the edge ring 11e is attracted to the second region 16R2 and is held by the second region 16R2.

In various exemplary embodiments, the electrostatic chuck 16 of the plasma processing apparatus 1 includes a part or an element (hereinafter referred to as an “adjuster”) configured to reduce a difference between an electrostatic capacity per unit area of the first region 16R1 and an electrostatic capacity per unit area of the second region 16R2. The electrostatic capacity per unit area of the first region 16R1 is an electrostatic capacity per unit area (or an average value of the electrostatic capacity) of the first region 16R1 between the upper surface (substrate support surface) of the first region 16R1 and the base 14. The electrostatic capacity per unit area of the second region 16R2 is an electrostatic capacity per unit area (or an average value of the electrostatic capacity) of the second region 16R2 between the upper surface (the edge ring support surface) of the second region 16R2 and the base 14. The adjuster is provided in at least one of the first region 16R1 and the second region 16R2.

The electrostatic chuck 16A illustrated in FIG. 3 includes a part 16pA (electrode structure) as an adjuster. The part 16pA is provided in the main body 16m within the first region 16R1. The part 16pA is provided between the chuck electrode 16a and a lower surface of the main body 16m. That is, the part 16pA is provided below the chuck electrode 16a.

The part 16pA includes a first electrode 161 (first electrode layer), a second electrode 162 (second electrode layer), and one or more interconnectors 163 (one or more connectors). Each of the first electrode 161 and the second electrode 162 is a film formed of a conductive material. Each of the first electrode 161 and the second electrode 162 may have a substantially circular planar shape. A center of each of the first electrode 161 and the second electrode 162 may be located on the central axis of the electrostatic chuck 16A. Further, the first electrode 161 and the second electrode 162 extend over the substrate support surface in a plan view. That is, the first electrode 161 and the second electrode 162 extend over the first region 16R1 in a horizontal direction. The first electrode 161 and the second electrode 162 may extend substantially over the entire region (e.g., a region of 90% or more) of the first region 16R1 in the horizontal direction.

The second electrode 162 extends below the first electrode 161. The one or more interconnectors 163 are formed of a conductive material. Each of the one or more interconnectors 163 may have a columnar shape. The one or more interconnectors 163 electrically connect the first electrode 161 and the second electrode 162 to each other. The electrostatic chuck 16A may include a plurality of interconnectors 163.

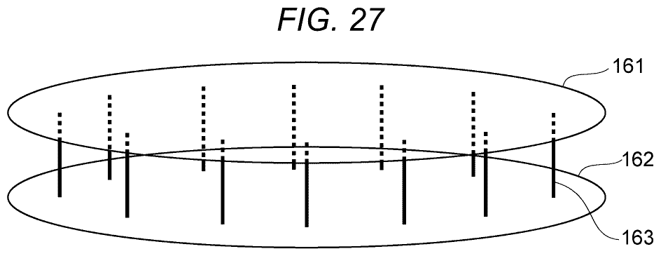

FIG. 27 is a perspective view of an electrode structure as an example. As illustrated in FIG. 27, the disposition of the plurality of interconnectors 163 may be axially symmetric. Further, the plurality of interconnectors 163 may be disposed at the same distance from a center of the first electrode 161 or the second electrode 162, or may be disposed at different distances. The plurality of interconnectors 163 may be arranged along a radial direction with respect to the center of the first electrode 161 or the second electrode 162.

The part 16pA is placed in an electrically floating state. In the present specification, the electric floating state of the electrode structure according to various exemplary embodiments such as the part 16pA is a state where the electrode structure is electrically floating or separated from either the power supply or the ground (ground potential), and refers to a state where there is no or almost no exchange of charges or currents with a peripheral conductor, and a current can flow exclusively in the object by electromagnetic induction.

According to the electrostatic chuck having the adjuster such as the part 16pA, even if the thickness of the first region 16R1 is larger than the thickness of the second region 16R2, the difference between the electrostatic capacity per unit area of the first region 16R1 and the electrostatic capacity per unit area of the second region 16R2 is small. Therefore, the difference between the impedance between the base 14 and the substrate W and the impedance between the base 14 and the edge ring 11e is small. Therefore, a difference between power coupled to a plasma via the edge ring 11e and power coupled to a plasma via the substrate W can be reduced.

Further, in a case where the bonding member 15 contains metal, heat transfer between the base 14 and the electrostatic chuck 16A is improved. Therefore, the temperature increases in the electrostatic chuck 16A, the substrate W, and the edge ring 11e can be prevented even when a level of the radio-frequency power RF and/or the bias energy BE is high.

Further, since the part 16pA is present in the first region 16R1, the electrostatic capacity of the first region 16R1 is large. Therefore, a large potential difference can be applied to a sheath on the substrate W. Therefore, power efficiencies of the radio-frequency power RF and the bias energy BE are improved.

Further, since the impedance in the first region 16R1 is small, the level of the radio-frequency power RF and/or the level of the bias energy BE can be reduced. Therefore, the discharge in the flow path in the substrate support 11A and the gap through which the heat transfer gas flows is prevented.

Further, the electrostatic chuck 16A does not have an electric contact with the part 16pA. Therefore, local heat due to an electric contact does not generate in the electrostatic chuck 16A. In another embodiment, the electrostatic chuck 16A may include a conductor portion 17 that electrically connects the part 16pA and the base 14 as illustrated in FIG. 3.

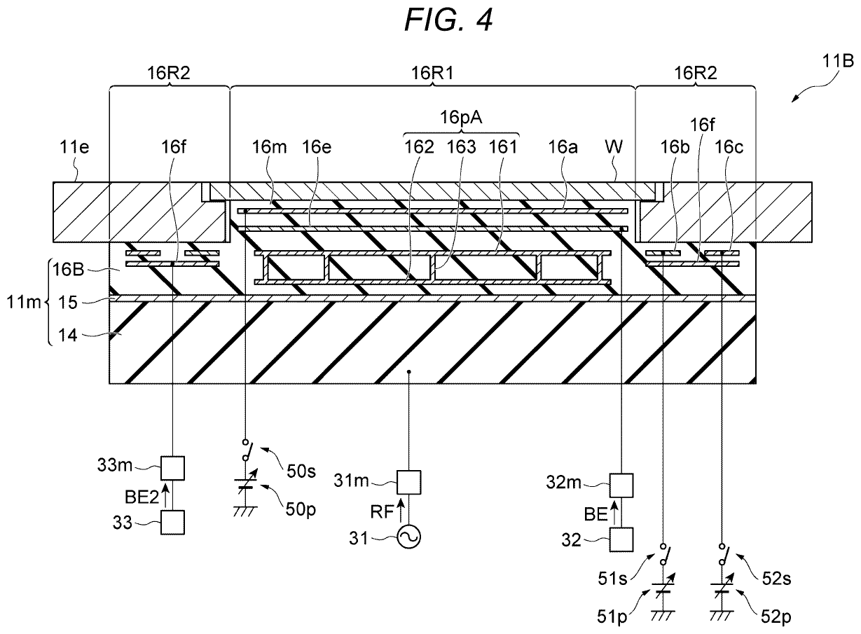

Hereinafter, FIG. 4 will be referred to. FIG. 4 is a diagram illustrating a substrate support according to another exemplary embodiment. A substrate support 11B illustrated in FIG. 4 may be used as the substrate support 11 of the plasma processing apparatus 1. Hereinafter, the differences between the substrate support 11B and the substrate support 11A will be described.

An electrostatic chuck 16B of the substrate support 11B differs from the electrostatic chuck 16A of the substrate support 11A in that the electrostatic chuck 16B includes bias electrodes 16e and 16f. Each of the bias electrodes 16e and 16f is a film formed of a conductive material. The bias electrode 16e is provided in the main body 16m within the first region 16R1. The bias electrode 16e extends over a substrate support surface in a plan view. That is, the bias electrode 16e extends over the first region 16R1 in the horizontal direction. The bias electrode 16e is provided between the upper surface of the first region 16R1 and the part 16pA. The bias electrode 16e may be provided between the chuck electrode 16a and the part 16pA. The planar shape of the bias electrode 16e may be substantially circular, and the center thereof may be positioned on the central axis of the electrostatic chuck 16B.

The bias electrode 16f is provided in the main body 16m within the second region 16R2. The bias electrode 16f may be provided between each of the chuck electrodes 16b and 16c and a lower surface of the second region 16R2. The planar shape of the bias electrode 16f may be a substantially ring shape, and the center thereof may be positioned on the central axis of the electrostatic chuck 16B.

The bias power supply 32 (first bias power supply) is electrically connected to the bias electrode 16e. A bias power supply 33 (second bias power supply) is electrically connected to the bias electrode 16f. The bias power supply 33 is a power supply that generates bias energy BE2 supplied to the bias electrode 16f. Similar to the bias energy BE, the bias energy BE2 may be the radio frequency bias power, or may be the pulse, which is periodically generated, of a voltage. In a case where the bias energy BE2 is the radio-frequency bias power, the bias power supply 33 is electrically connected to the bias electrode 16f via a matcher 33m.

The substrate support 11B can apply the bias energy BE having a relatively low frequency to the bias electrode 16e provided near the substrate W. Further, the bias energy BE2 having a relatively low frequency can be applied to the bias electrode 16f provided near the edge ring 11e.

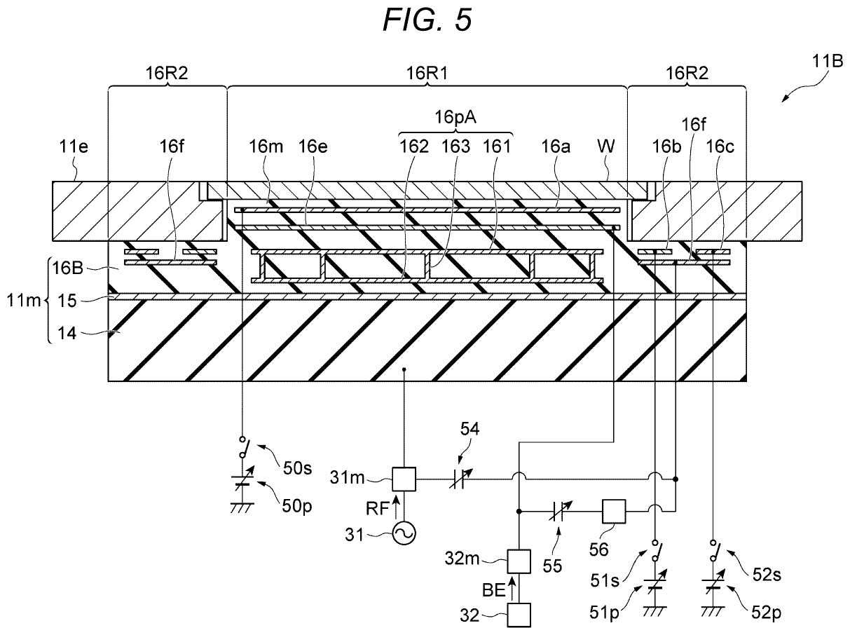

Hereinafter, FIG. 5 will be referred to. FIG. 5 is a diagram illustrating a substrate support according to still another exemplary embodiment. In the embodiment illustrated in FIG. 5, the bias power supply 32 is electrically connected to both the bias electrodes 16e and 16f, and the bias energy BE is distributed to the bias electrodes 16e and 16f. The distribution ratio of the bias energy BE between the bias electrode 16e and the bias electrode 16f is adjusted by an impedance adjuster 55. The impedance adjuster 55 includes, for example, a variable capacitor. the impedance adjuster 55 is connected between the bias power supply 32 and the bias electrode 16f. Further, another impedance adjuster may be connected between the bias power supply 32 and the bias electrode 16e. Alternatively, the impedance adjuster 55 may be connected between the bias power supply 32 and the bias electrode 16e.

Further, in the embodiment illustrated in FIG. 5, the radio-frequency power supply 31 is electrically connected to the bias electrode 16f in addition to the base 14, and the radio-frequency power RF is distributed between the base 14 and the bias electrode 16f. The distribution ratio of the radio-frequency power RF between the base 14 and the bias electrode 16f is adjusted by an impedance adjuster 54. The impedance adjuster 54 includes, for example, a variable capacitor. The impedance adjuster 54 is connected between the radio-frequency power supply 31 and the bias electrode 16f. Further, another impedance adjuster may be connected between the radio-frequency power supply 31 and the base 14. Alternatively, the impedance adjuster 54 may be connected between the radio-frequency power supply 31 and the base 14.

As illustrated in FIG. 5, an electric path provided between the radio-frequency power supply 31 and the bias electrode 16f is connected to a node on an electric path that connects the bias power supply 32 to the bias electrode 16f. In the embodiment illustrated in FIG. 5, a low-pass filter 56 is connected between the node and the bias power supply 32 to block or attenuate the radio-frequency power RF flowing toward the bias power supply 32. The low-pass filter 56 has a characteristic of passing the bias energy BE. The low-pass filter 56 may be connected between the node and the impedance adjuster 55. Further, a low-pass filter such as the low-pass filter 56 may be connected between the bias electrode 16e and a branch node where the two electric paths respectively connecting the bias power supply 32 to the bias electrodes 16e and 16f branch from each other. Alternatively, a low-pass filter such as the low-pass filter 56 may be connected between the branch node and the bias power supply 32.

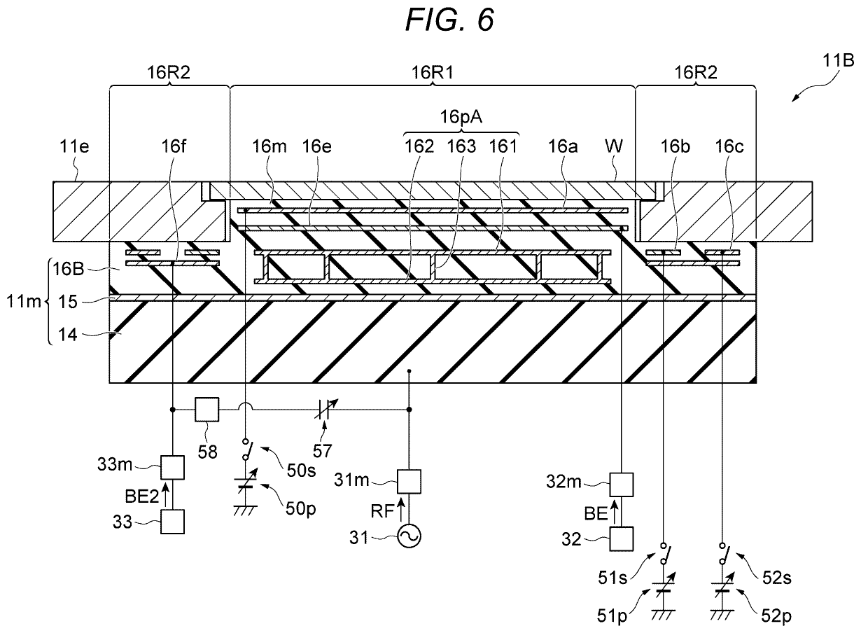

Hereinafter, FIG. 6 will be referred to. FIG. 6 is a diagram illustrating a substrate support according to still another exemplary embodiment. In the embodiment illustrated in FIG. 6, the bias power supply 32 is connected to the bias electrode 16e, and the bias power supply 33 is connected to the bias electrode 16f.

Further, in the embodiment illustrated in FIG. 6, the radio-frequency power supply 31 is electrically connected to the bias electrode 16f in addition to the base 14, and the radio-frequency power RF is distributed between the base 14 and the bias electrode 16f. A distribution ratio of the radio-frequency power RF between the base 14 and the bias electrode 16f is adjusted by an impedance adjuster 57. The impedance adjuster 57 includes, for example, a variable capacitor. The impedance adjuster 57 is connected between the radio-frequency power supply 31 and the bias electrode 16f. Further, another impedance adjuster may be connected between the radio-frequency power supply 31 and the base 14. Alternatively, the impedance adjuster 57 may be connected between the radio-frequency power supply 31 and the base 14.

As illustrated in FIG. 6, an electric path provided between the radio-frequency power supply 31 and the bias electrode 16f is connected to a node on an electric path that connects the bias power supply 33 to the bias electrode 16f In the embodiment illustrated in FIG. 6, a high-pass filter 58 is connected between the node and the radio-frequency power supply 31 to block or attenuate the bias energy BE2 flowing toward the radio-frequency power supply 31. The high-pass filter 58 has a characteristic of passing the radio-frequency power RF. The high-pass filter 58 may be connected between the node and the impedance adjuster 57. Further, a high-pass filter such as the high-pass filter 58 may be connected between the base 14 and the branch node where the two electric paths respectively connecting the radio-frequency power supply 31 to the base 14 and the bias electrode 16f branch from each other. Alternatively, a high-pass filter such as the high-pass filter 58 may be connected between the branch node and the radio-frequency power supply 31.

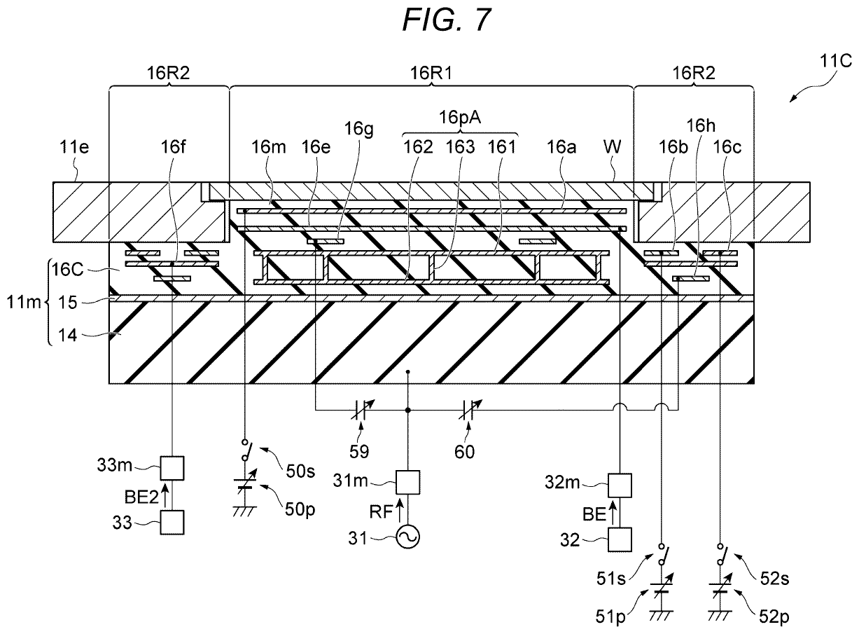

Hereinafter, FIG. 7 will be referred to. FIG. 7 is a diagram illustrating a substrate support according to still another exemplary embodiment. A substrate support 11C illustrated in FIG. 7 may be used as the substrate support 11 of the plasma processing apparatus 1. Hereinafter, the differences between the substrate support 11C and the substrate support 11B will be described.

An electrostatic chuck 16C of the substrate support 11C is different from the electrostatic chuck 16B of the substrate support 11B in that the electrostatic chuck 16C further includes auxiliary electrodes 16g and 16h. Each of the auxiliary electrodes 16g and 16h is a film formed of a conductive material. The auxiliary electrode 16g is provided in the main body 16m within the first region 16R1. The auxiliary electrode 16g is provided between the upper surface of the first region 16R1 and the part 16pA. The auxiliary electrode 16g may be provided between the bias electrode 16e and the part 16pA. The auxiliary electrode 16g may have a substantially annular shape in a plan view, and a center thereof may be located on a central axis of the electrostatic chuck 16C.

The auxiliary electrode 16h is provided in the main body 16m within the second region 16R2. The auxiliary electrode 16h may be provided between the bias electrode 16f and the lower surface of the second region 16R2. The auxiliary electrode 16h may have a substantially annular shape in a plan view, and the center thereof may be located on a central axis of the electrostatic chuck 16C.

As illustrated in FIG. 7, the radio-frequency power supply 31 is electrically connected to the auxiliary electrodes 16g and 16h in addition to the base 14, and the radio-frequency power RF is distributed to the base 14, the auxiliary electrode 16g, and the auxiliary electrode 16h. A distribution ratio of the radio-frequency power RF to the base 14, the auxiliary electrode 16g, and the auxiliary electrode 16h is adjusted by impedance adjusters 59 and 60. Each of the impedance adjusters 59 and 60 includes, for example, a variable capacitor. The impedance adjuster 59 is connected between the radio-frequency power supply 31 (or the matcher 31m) and the auxiliary electrode 16g. The impedance adjuster 60 is connected between the radio-frequency power supply 31 (or the matcher 31m) and the auxiliary electrode 16h. One of the impedance adjusters 59 and 60 may be connected between the radio-frequency power supply 31 (or the matcher 31m) and the base 14. Alternatively, another impedance adjuster may be connected between the radio-frequency power supply 31 and the base 14.

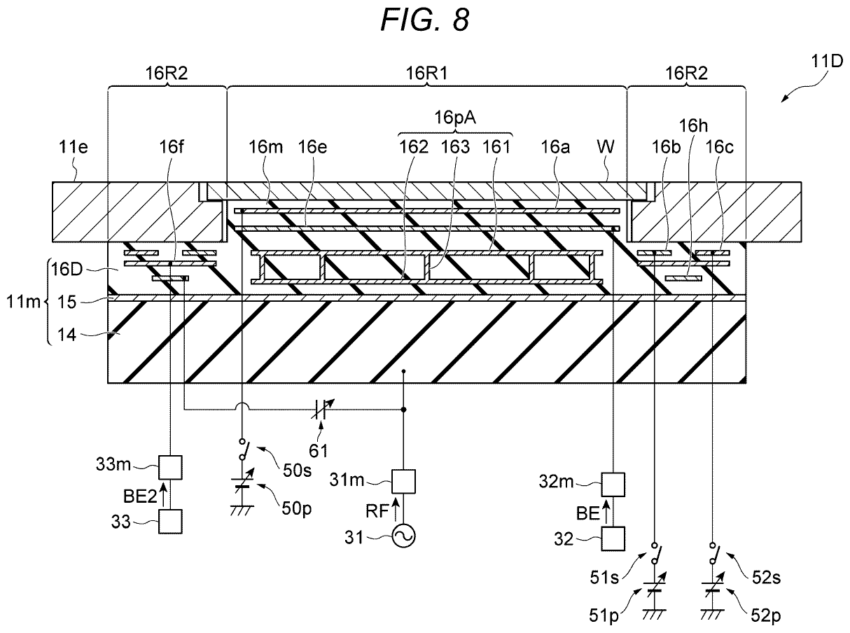

Hereinafter, FIG. 8 will be referred to. FIG. 8 is a diagram illustrating a substrate support according to still another exemplary embodiment. A substrate support 11D illustrated in FIG. 8 may be used as the substrate support 11 of the plasma processing apparatus 1. Hereinafter, the differences between the substrate support 11D and the substrate support 11C will be described.

An electrostatic chuck 16D of the substrate support 11D is different from the electrostatic chuck 16C of the substrate support 11C in that the electrostatic chuck 16D does not have the auxiliary electrode 16g. As illustrated in FIG. 8, the radio-frequency power supply 31 is electrically connected to the auxiliary electrode 16h in addition to the base 14, and the radio-frequency power RF is distributed to the base 14 and the auxiliary electrode 16h. A distribution ratio of the radio-frequency power RF between the base 14 and the auxiliary electrode 16h is adjusted by an impedance adjuster 61. The impedance adjuster 61 includes, for example, a variable capacitor. The impedance adjuster 61 is connected between the radio-frequency power supply 31 (or the matcher 31m) and the auxiliary electrode 16h. The impedance adjuster 61 may be connected between the radio-frequency power supply 31 (or the matcher 31m) and the base 14. Alternatively, another impedance adjuster may be connected between the radio-frequency power supply 31 and the base 14.

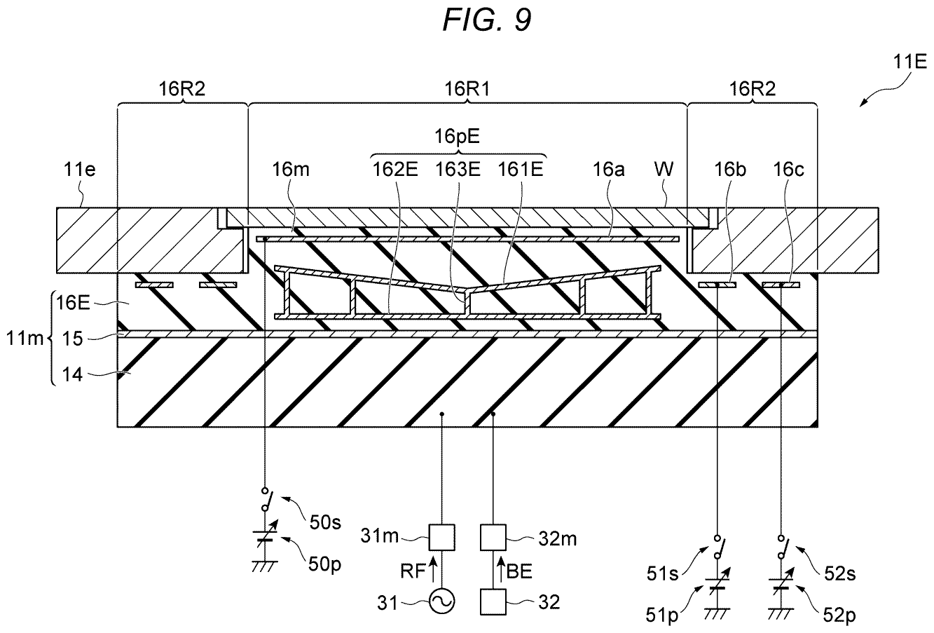

Hereinafter, FIG. 9 will be referred to. FIG. 9 is a diagram illustrating a substrate support according to still another exemplary embodiment. A substrate support 11E illustrated in FIG. 9 may be used as the substrate support 11 of the plasma processing apparatus 1. Hereinafter, the differences between the substrate support 11E and the substrate support 11A will be described.

An electrostatic chuck 16E of the substrate support 11E is different from the electrostatic chuck 16A of the substrate support 11A in that the electrostatic chuck 16E includes a part 16pE (electrode structure) as an adjuster. The part 16pE is provided in the main body 16m within the first region 16R1. The part 16pE may be provided between the chuck electrode 16a and a lower surface of the first region 16R1.

The part 16pE includes a first electrode 161E (first electrode layer), a second electrode 162E (second electrode layer), and one or more interconnectors 163E (one or more connectors). Each of the first electrode 161E and the second electrode 162E is a film formed of a conductive material. Each of the first electrode 161E and the second electrode 162E may have a substantially circular planar shape. A center of each of the first electrode 161E and the second electrode 162E may be located on a central axis of the electrostatic chuck 16E. Further, the first electrode 161E and the second electrode 162E extend over the substrate support surface in a plan view. That is, the first electrode 161E and the second electrode 162E extend over the first region 16R1 in the horizontal direction. The first electrode 161E and the second electrode 162E may extend over substantially the entire region (e.g., a region of 90% or more) of the first region 16R1 in the horizontal direction.

The second electrode 162E extends below the first electrode 161E. The one or more interconnectors 163E are formed of a conductive material. Each of the one or more interconnectors 163E may have a columnar shape. Similar to the interconnector 163, the one or more interconnectors 163E electrically connect the first electrode 161E and the second electrode 162E to each other. The electrostatic chuck 16E may include a plurality of interconnectors 163E.

The first electrode 161E is formed such that a distance between the first electrode 161E and the upper surface of the first region 16R1 gradually decreases as a distance from a center of the first region 16R1 in a radial direction increases.

According to the electrostatic chuck 16E, the electrostatic capacity of the first region 16R1 increases as the distance from the center of the first region 16R1 in the radial direction increases. Therefore, it is possible to correct the distribution of the density of a plasma that decreases as a distance from a central axis of the electrostatic chuck 16E in the radial direction increases.

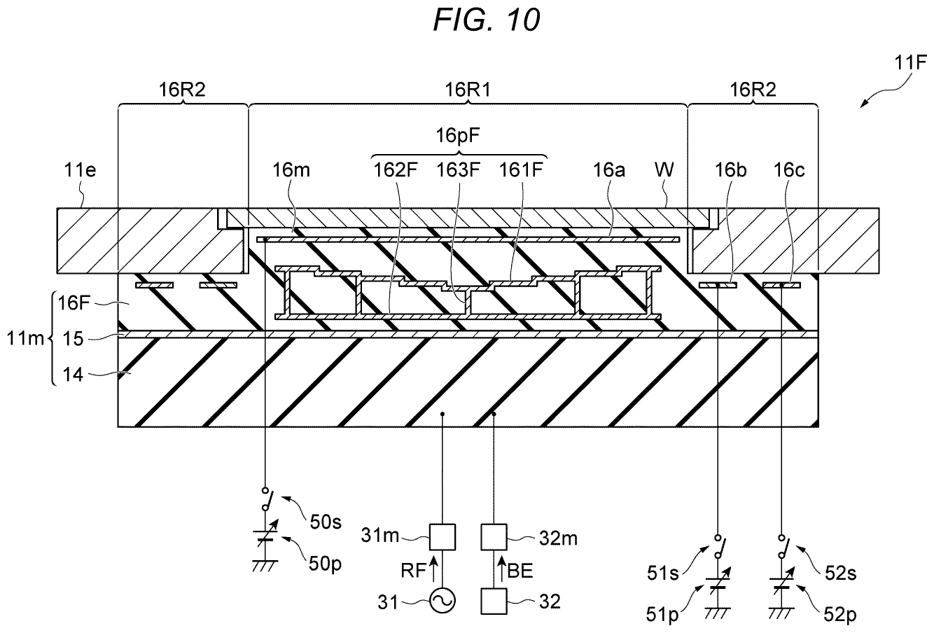

Hereinafter, FIG. 10 will be referred to. FIG. 10 is a diagram illustrating a substrate support according to still another exemplary embodiment. A substrate support 11F illustrated in FIG. 10 can be used as the substrate support 11 of the plasma processing apparatus 1. Hereinafter, the differences between the substrate support 11F and the substrate support IE will be described.

An electrostatic chuck 16F of the substrate support 11F is different from the electrostatic chuck 16E of the substrate support 11E in that the electrostatic chuck 16F includes a part 16pF (electrode structure) as an adjuster. The part 16pF is provided in the main body 16m within the first region 16R1. The part 16pF may be provided between the chuck electrode 16a and the lower surface of the first region 16R1.

The part 16pF includes a first electrode 161F (first electrode layer), a second electrode 162F (second electrode layer), and one or more interconnectors 163F (one or more connectors). Each of the first electrode 161F and the second electrode 162F is a film formed of a conductive material. Each of the first electrode 161F and the second electrode 162F may have a substantially circular planar shape. A center of each of the first electrode 161F and the second electrode 162F may be located on a central axis of the electrostatic chuck 16F. Further, the first electrode 161F and the second electrode 162F extend over the substrate support surface in a plan view. That is, the first electrode 161F and the second electrode 162F extend over the first region 16R1 in the horizontal direction. The first electrode 161F and the second electrode 162F may extend over substantially the entire region (e.g., a region of 90% or more) of the first region 16R1 in the horizontal direction.

The second electrode 162F extends below the first electrode 161F. The one or more interconnectors 163F are formed of a conductive material. Each of the one or more interconnectors 163F may have a columnar shape. Similar to the interconnectors 163, the one or more interconnectors 163F electrically connect the first electrode 161F and the second electrode 162F to each other. The electrostatic chuck 16F may include a plurality of interconnectors 163F.

The first electrode 161F is formed such that a distance between the first electrode 161F and the upper surface of the first region 16R1 decreases stepwise as a distance from the center of the first region 16R1 in the radial direction increases.

According to the electrostatic chuck 16F, the electrostatic capacity of the first region 16R1 increases stepwise as the distance from the center of the first region 16R1 in the radial direction increases. Therefore, it is possible to correct the distribution of the density of a plasma that decreases as a distance from a central axis of the electrostatic chuck 16E in the radial direction increases.

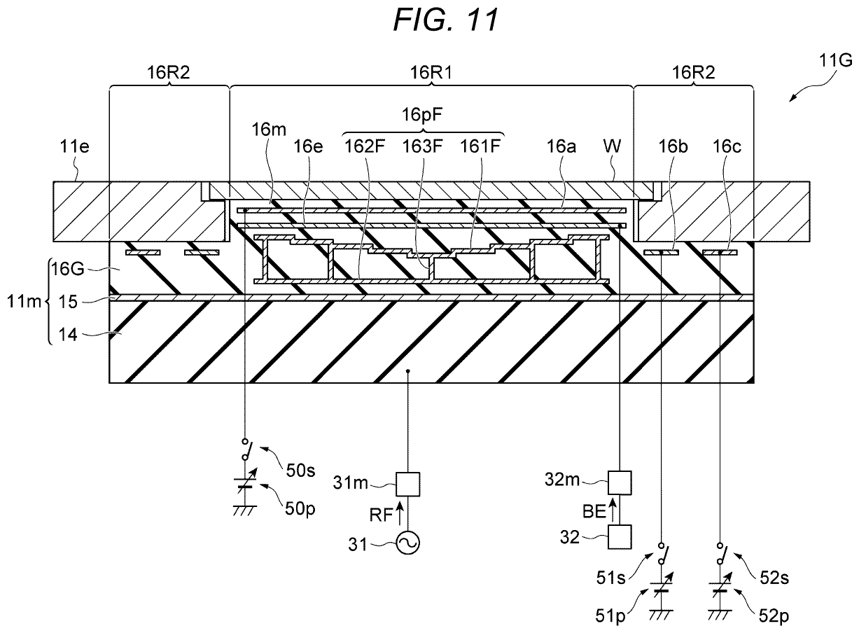

Hereinafter, FIG. 11 will be referred to. FIG. 11 is a diagram illustrating a substrate support according to still another exemplary embodiment. A substrate support 11G illustrated in FIG. 11 may be used as the substrate support 11 of the plasma processing apparatus 1. Hereinafter, the differences between the substrate support 11G and the substrate support 11F will be described.

An electrostatic chuck 16G of the substrate support 11G is different from the electrostatic chuck 16F of the substrate support 11F in that the electrostatic chuck 16G further includes the bias electrode 16e. The bias electrode 16e is a film formed of a conductive material. The bias electrode 16e is provided in the main body 16m within the first region 16R1. The bias electrode 16e extends over a substrate support surface in a plan view. That is, the bias electrode 16e extends over the first region 16R1 in the horizontal direction. The bias electrode 16e is provided between the upper surface of the first region 16R1 and the part 16pF. The planar shape of the bias electrode 16e may be substantially circular, and a center thereof may be located on a central axis of the electrostatic chuck 16B. The bias electrode 16e is electrically connected to the bias power supply 32.

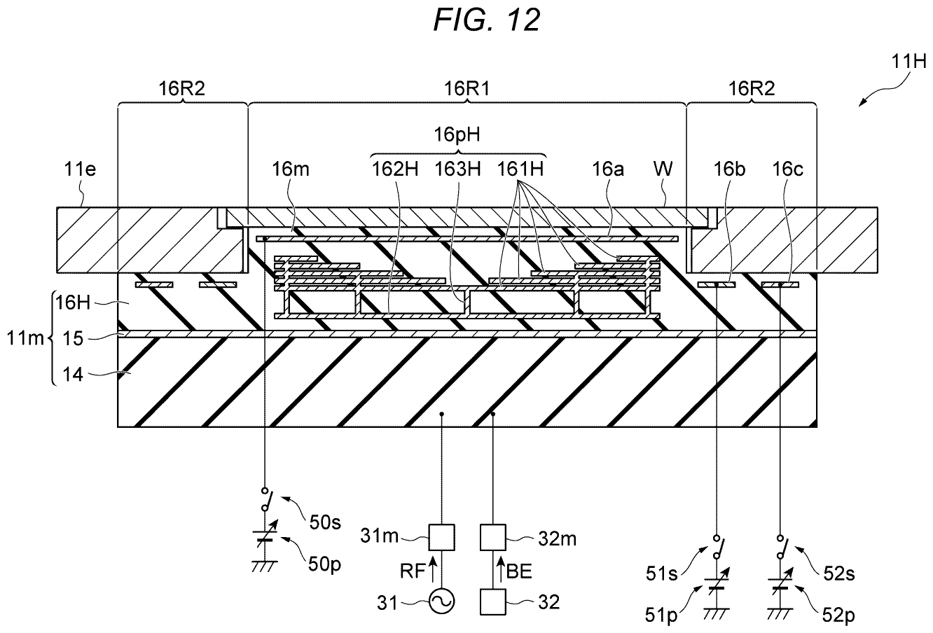

Hereinafter, FIG. 12 will be referred to. FIG. 12 is a diagram illustrating a substrate support according to still another exemplary embodiment. A substrate support 11H illustrated in FIG. 12 may be used as the substrate support 11 of the plasma processing apparatus 1. Hereinafter, the differences between the substrate support 11H and the substrate support 11F will be described.

An electrostatic chuck 16H of the substrate support 11H is different from the electrostatic chuck 16F of the substrate support 11F in that the electrostatic chuck 16H includes a part 16pH (electrode structure) as an adjuster. The part 16pH is provided in the main body 16m within the first region 16R1. The part 16pH may be provided between the chuck electrode 16a and the lower surface of the first region 16R1.

The part 16pH includes a first electrode 161H (first electrode layer), a second electrode 162H (second electrode layer), and one or more interconnectors 163H (one or more connectors). The first electrode 161H contains a plurality of films formed of a conductive material. The second electrode 162H is a film formed of a conductive material. A center of each of the first electrode 161H and the second electrode 162H may be located on a central axis of the electrostatic chuck 16H. Further, the first electrode 161H and the second electrode 162H extend over the substrate support surface in a plan view. That is, the first electrode 161H and the second electrode 162H extend over the first region 16R1 in the horizontal direction. The first electrode 161H and the second electrode 162H may extend over substantially the entire region (e.g., a region of 90% or more) of the first region 16R1 in the horizontal direction.

The second electrode 162H extends below the first electrode 161H. The one or more interconnectors 163H are formed of a conductive material. Each of the one or more interconnectors 163H may have a columnar shape. The one or more interconnectors 163H electrically connect the first electrode 161H and the second electrode 162H to each other. The electrostatic chuck 16H may include a plurality of interconnectors 163H.

The above-described plurality of films forming the first electrode 161H are formed such that a distance between the first electrode 161H and the upper surface of the first region 16R1 decreases stepwise as a distance from the center of the first region 16R1 in the radial direction increases. That is, the plurality of films form a stepped upper surface of the first electrode 161H.

According to the electrostatic chuck 16H, the electrostatic capacity of the first region 16R1 increases stepwise as the distance from the center of the first region 16R1 in the radial direction increases. Therefore, it is possible to correct the distribution of the density of a plasma that decreases as a distance from a central axis of the electrostatic chuck 16H in the radial direction increases.

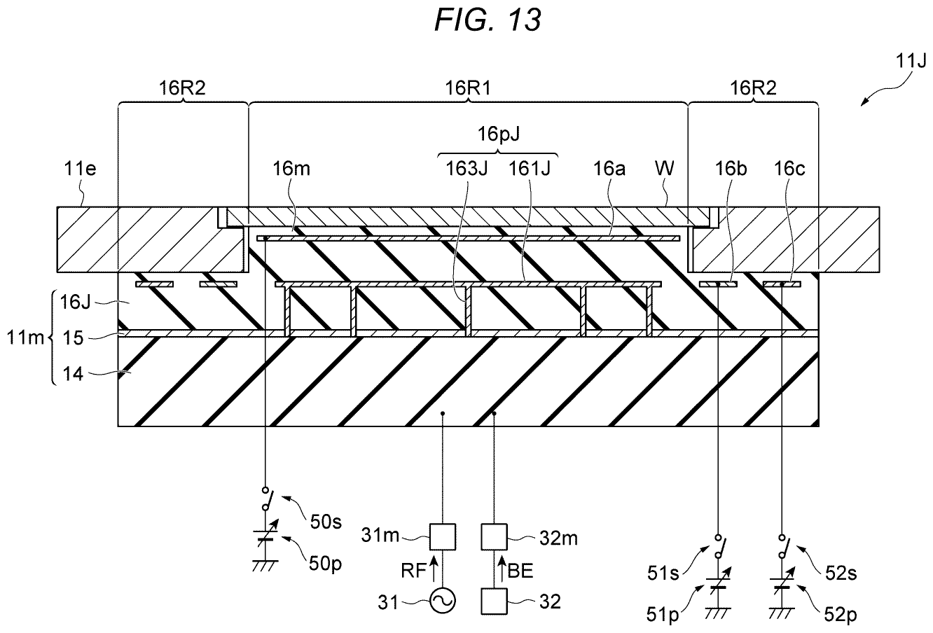

Hereinafter, FIG. 13 will be referred to. FIG. 13 is a diagram illustrating a substrate support according to still another exemplary embodiment. A substrate support 11J illustrated in FIG. 13 may be used as the substrate support 11 of the plasma processing apparatus 1. Hereinafter, the differences between the substrate support 11J and the substrate support 11A will be described.

An electrostatic chuck 16J of the substrate support 11J is different from the electrostatic chuck 16A of the substrate support 11A in that the electrostatic chuck 16J includes a part 16pJ (electrode structure) as an adjuster. The part 16pJ is provided in the main body 16m within the first region 16R1. The part 16pJ may be provided between the chuck electrode 16a and the base 14.

The part 16pJ includes an electrode 161J and one or more interconnectors 163J (one or more connectors). The electrode 161J is a film formed of a conductive material. The electrode 161J may have a substantially circular planar shape. A center of the electrode 161J may be located on a central axis of the electrostatic chuck 16J. Further, the electrode 161J extends over the substrate support surface in a plan view. That is, the electrode 161J extends over the first region 16R1 in the horizontal direction. The electrode 161J may extend over substantially the entire region (e.g., a region of 90% or more) of the first region 16R1 in the horizontal direction.

The one or more interconnectors 163J are formed of a conductive material. Each of the one or more interconnectors 163J may have a columnar shape. The one or more interconnectors 163J electrically connect the electrode 161J and an upper surface of the base 14 to each other. The electrostatic chuck 16J may include a plurality of interconnectors 163J. In order to prevent discharge and/or heat generation, the plurality of interconnectors 163J may be uniformly disposed in an annular shape, a concentric circle shape, or a grid shape when viewing the substrate support 11J from the upper surface thereof.

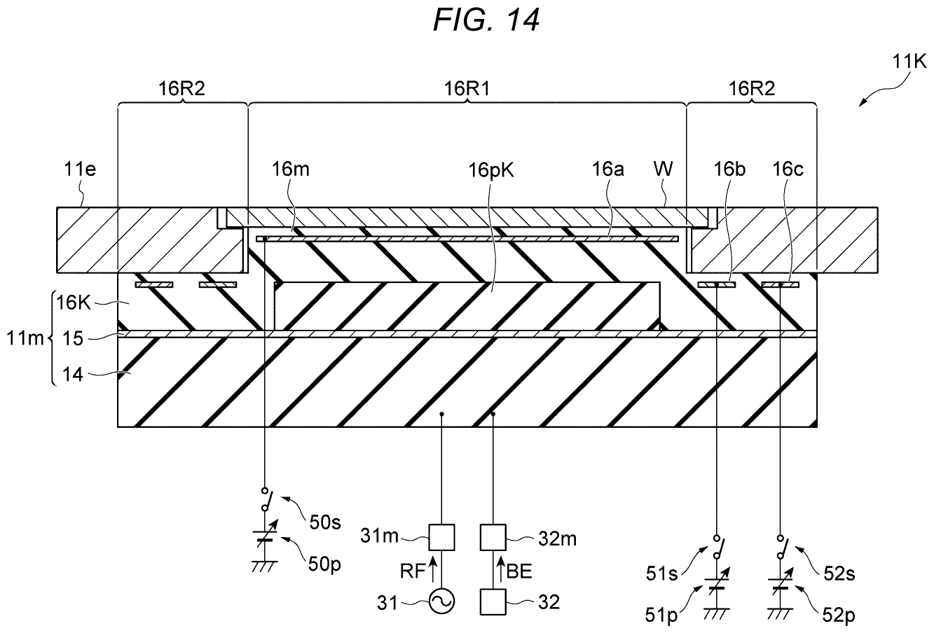

Hereinafter, FIG. 14 will be referred to. FIG. 14 is a diagram illustrating a substrate support according to still another exemplary embodiment. A substrate support 11K illustrated in FIG. 14 may be used as the substrate support 11 of the plasma processing apparatus 1. Hereinafter, the differences between the substrate support 11K and the substrate support 11A will be described.

An electrostatic chuck 16K of the substrate support 11K is different from the electrostatic chuck 16A of the substrate support 11A in that the electrostatic chuck 16K includes a part 16pK as an adjuster. The part 16pK is provided in the main body 16m within the first region 16R1. The part 16pK may be provided between the chuck electrode 16a and the base 14.

The part 16pK is a conductor plate formed of a metal such as aluminum. The part 16pK may have a substantially disc shape. A central axis of the part 16pK may substantially coincide with a central axis of the electrostatic chuck 16K. The part 16pK may have the largest thickness among all the conductor portions within the first region 16R1. A bonding member similar to the bonding member 15 may be interposed between the part 16pK and the main body 16m. Further, the part 16pK may be integrated with the base 14.

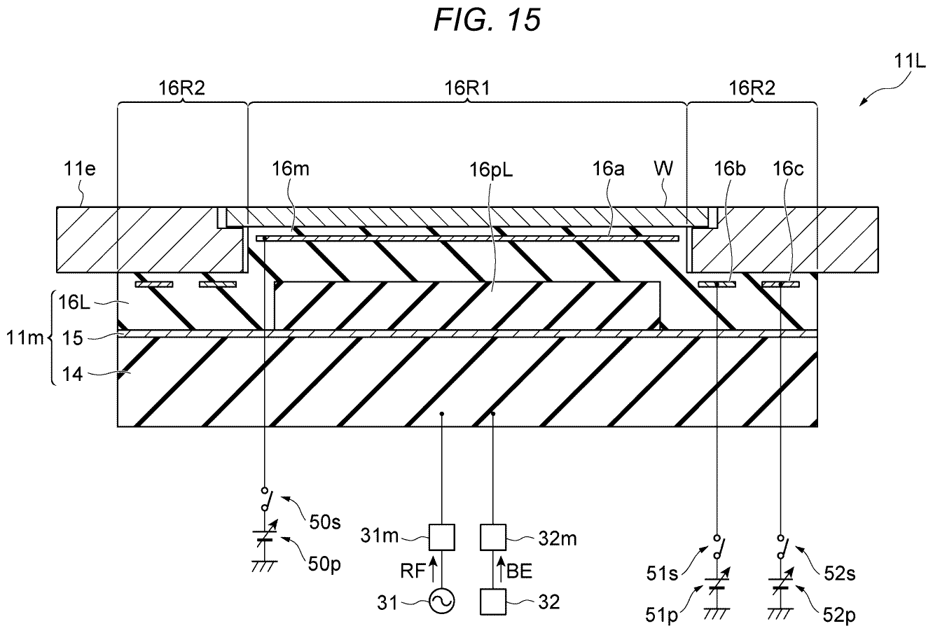

Hereinafter, FIG. 15 will be referred to. FIG. 15 is a diagram illustrating a substrate support according to still another exemplary embodiment. A substrate support 11L illustrated in FIG. 15 may be used as the substrate support 11 of the plasma processing apparatus 1. Hereinafter, the differences between the substrate support 11L and the substrate support 11A will be described.

The electrostatic chuck 16L of the substrate support 11L is different from the electrostatic chuck 16A of the substrate support 11A in that the electrostatic chuck 16L includes a part 16pL as an adjuster. The part 16pL constitutes a part of the first region 16R1, and is provided in the main body 16m within the first region 16R1. The part 16pL may be provided between the chuck electrode 16a and the base 14. The part 16pL may have a substantially disc shape. A central axis of the part 16pL may substantially coincide with a central axis of the electrostatic chuck 16L. The part 16pL is formed of a metal-based composite material, i.e., a composite material of ceramic and metal.

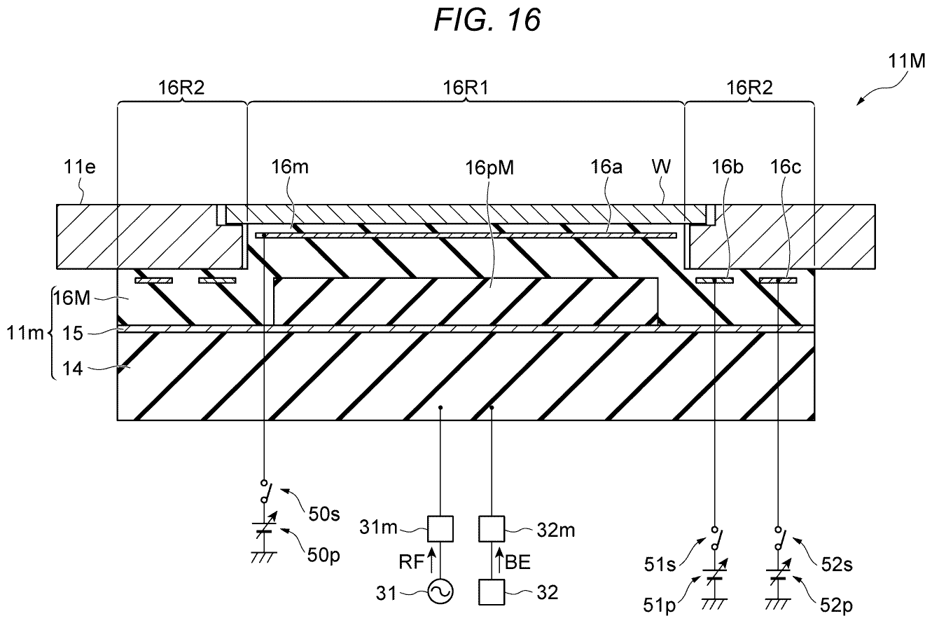

Hereinafter, FIG. 16 will be referred to. FIG. 16 is a diagram illustrating a substrate support according to still another exemplary embodiment. A substrate support 11M illustrated in FIG. 16 may be used as the substrate support 11 of the plasma processing apparatus 1. Hereinafter, the differences between the substrate support 11M and the substrate support 11L will be described.

An electrostatic chuck 16M of the substrate support 11M is different from the electrostatic chuck 16L of the substrate support 11L in that the electrostatic chuck 16M includes a part 16pM as an adjuster. The part 16pM constitutes a part of the first region 16R1, and is provided in the main body 16m within the first region 16R1. The part 16pM may be provided between the chuck electrode 16a and the base 14. The part 16pM may have a substantially disc shape. A central axis of the part 16pM may substantially coincide with a central axis of the electrostatic chuck 16M.

The part 16pM is formed of a material having a dielectric constant higher than a dielectric constant of a dielectric material of the main body 16m constituting the second region 16R2. For example, the part 16pM is formed of zirconia, hafnium oxide, barium magnesium niobate, or barium neodynate titanate.

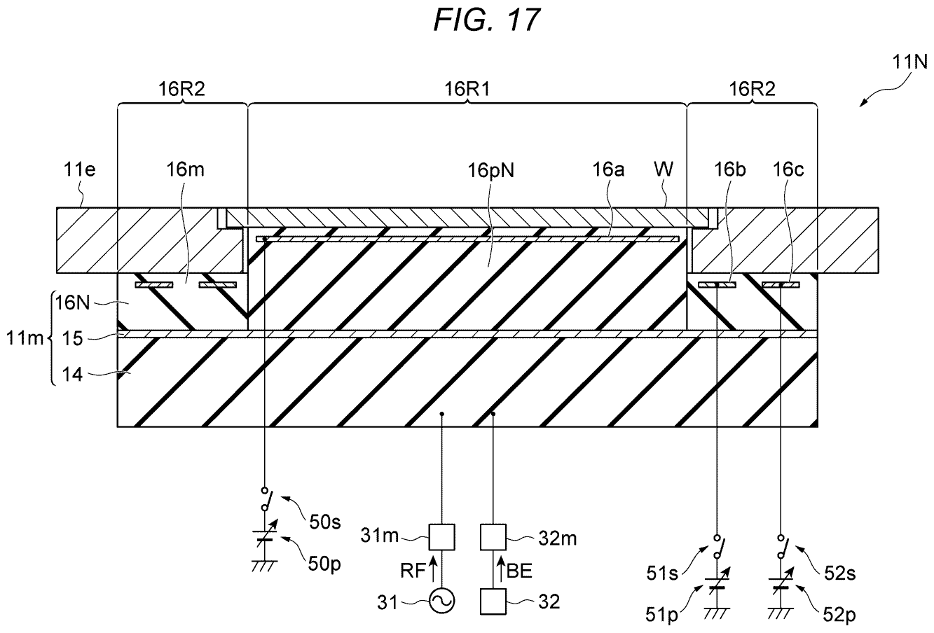

Hereinafter, FIG. 17 will be referred to. FIG. 17 is a diagram illustrating a substrate support according to still another exemplary embodiment. A substrate support 11N illustrated in FIG. 17 may be used as the substrate support 11 of the plasma processing apparatus 1. Hereinafter, the differences between the substrate support 11N and the substrate support 11M will be described.

An electrostatic chuck 16N of the substrate support 11N is different from the electrostatic chuck 16M of the substrate support 11M in that the electrostatic chuck 16N includes a part 16pN as an adjuster. The part 16pN constitutes substantially the entire first region 16R1. That is, the part 16pN constitutes a part other than the chuck electrode 16a of the first region 16R1. The part 16pN is formed of the same material as a material forming the part 16pM.

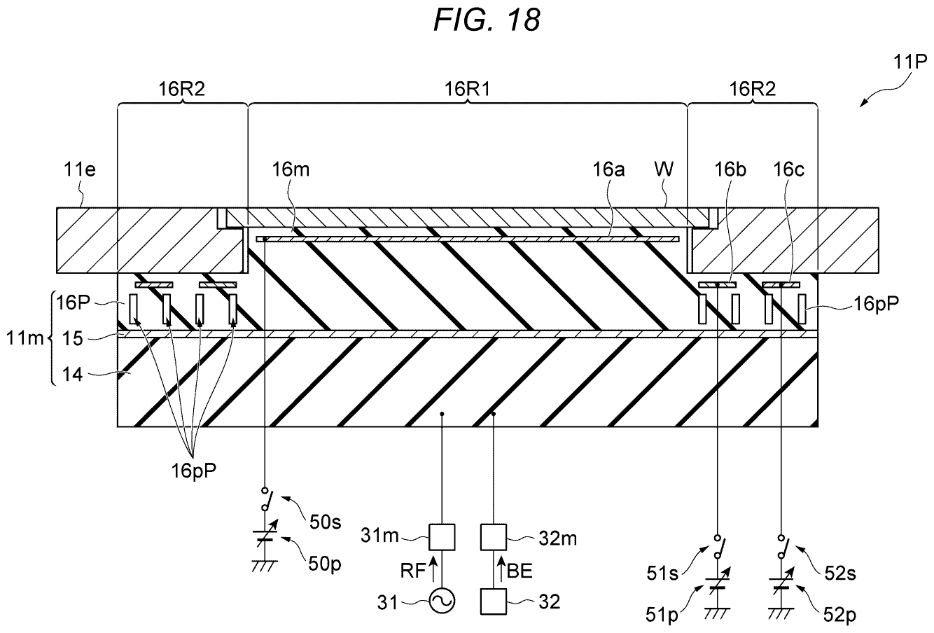

Hereinafter, FIG. 18 will be referred to. FIG. 18 is a diagram illustrating a substrate support according to still another exemplary embodiment. A substrate support 11P illustrated in FIG. 18 may be used as the substrate support 11 of the plasma processing apparatus 1. Hereinafter, the differences between the substrate support 11P and the substrate support 11A will be described.

An electrostatic chuck 16P of the substrate support 11P includes a part 16pP as an adjuster. The part 16pP is one or more cavities and is provided in the main body 16m within the second region 16R2. The one or more cavities constituting the part 16pP may extend in a circumferential direction with respect to a central axis of the electrostatic chuck 16P or may be arranged along the circumferential direction. A material having a dielectric constant lower than a dielectric constant of the main body 16m may be provided in the one or more cavities constituting the part 16pP. The first region 16R1 may also have one or more cavities.

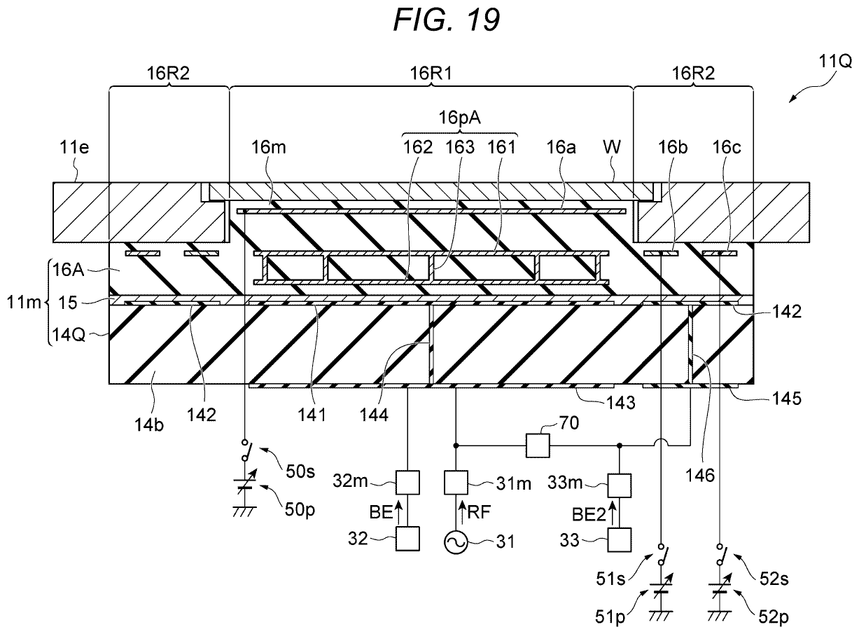

Hereinafter, FIG. 19 will be referred to. FIG. 19 is a diagram illustrating a substrate support according to still another exemplary embodiment. A substrate support 11Q illustrated in FIG. 19 may be used as the substrate support 11 of the plasma processing apparatus 1. Hereinafter, the differences between the substrate support 11Q and the substrate support 11A will be described.

The substrate support 11Q is different from the substrate support 11A in that the substrate support 11Q includes a base 14Q instead of the base 14. The base 14Q includes a base part 14b (an insulating member), a first electrode film 141, and a second electrode film 142. The base part 14b is formed of an insulator such as SiC and has a substantially disc shape. The first electrode film 141 is provided below the first region 16R1 and on the upper surface of the base part 14b. The second electrode film 142 is provided below the second region 16R2 and on the upper surface of the base part 14b.

As illustrated in FIG. 19, the radio-frequency power supply 31 and the bias power supply 32 (first bias power supply) are connected to the first electrode film 141. In one embodiment, the radio-frequency power supply 31 and the bias power supply 32 may be connected to the first electrode film 141 via the electrode film 143 and the wiring 144. The electrode film 143 is formed below the first region 16R1 and on the lower surface of the base part 14b. The electrode film 143 is connected to the first electrode film 141 via the wiring 144. The wiring 144 may be a via formed in the base part 14b. The first electrode film 141 may be formed on a bottom surface of the electrostatic chuck 16A in the first region 16R1, and may be supplied with power via the wiring 144.

The bias power supply 33 (second bias power supply) is connected to the second electrode film 142. In one embodiment, the bias power supply 33 may be connected to the second electrode film 142 via an electrode film 145 and a wiring 146. The electrode film 145 is formed below the second region 16R2 and on the lower surface of the base part 14b. The electrode film 145 is connected to the second electrode film 142 via the wiring 146. The wiring 146 may be a via formed in the base part 14b. The second electrode film 142 may be formed on the bottom surface of the electrostatic chuck 16A in the second region 16R2, and may be supplied with power via the wiring 146.

The radio-frequency power supply 31 is further connected to the second electrode film 142. An electric path extending between the radio-frequency power supply 31 and the second electrode film 142 is connected to a node on the electric path that connects the bias power supply 32 to the second electrode film 142. A high-pass filter 70 is connected between the node and the radio-frequency power supply 31. The high-pass filter 70 has a characteristic of blocking or attenuating the bias energy BE2 flowing toward the radio-frequency power supply 31, and passes the radio-frequency power RF.

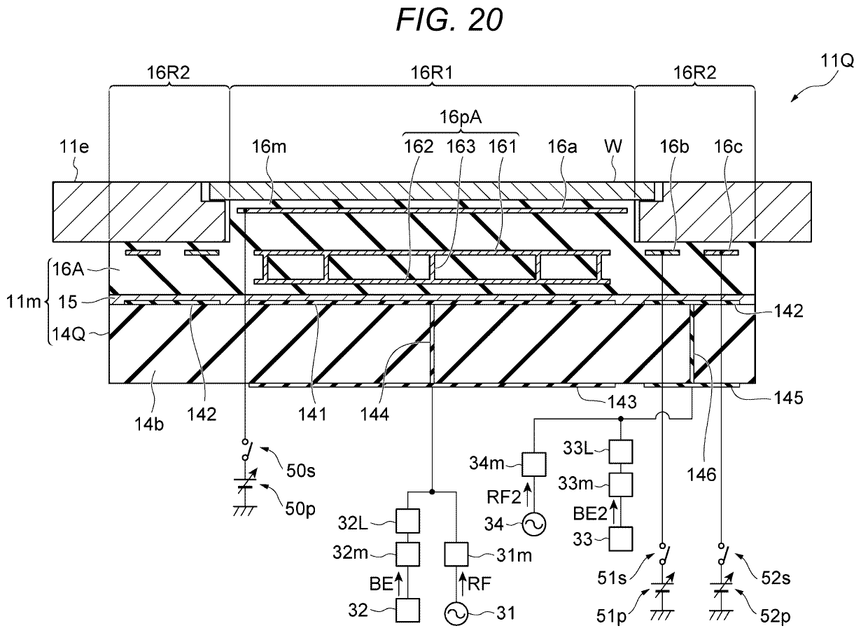

Hereinafter, FIG. 20 will be referred to. FIG. 20 is a diagram illustrating a substrate support according to still another exemplary embodiment. Hereinafter, differences between the embodiment illustrated in FIG. 20 and the embodiment illustrated in FIG. 19 will be described.

In the embodiment illustrated in FIG. 20, the radio-frequency power supply 31 is not electrically connected to the second electrode film 142, and is electrically connected to the first electrode film 141 (or the electrode film 143) together with the bias power supply 32. Further, a low-pass filter 32L is connected between the first electrode film 141 and the bias power supply 32. The low-pass filter 32L has a characteristic of blocking or attenuating the radio-frequency power RF and passing the bias energy BE2.

In the embodiment illustrated in FIG. 20, a radio-frequency power supply 34 is electrically connected to the second electrode film 142 (or the electrode film 145) together with the bias power supply 33. The radio-frequency power supply 34 is configured to generate radio-frequency power RF2 similar to the radio-frequency power RF. The radio-frequency power supply 34 is electrically connected to the second electrode film 142 via a matcher 34m. The matcher 34m has a matching circuit for matching the impedance on the load of the radio-frequency power supply 34 with the output impedance of the radio-frequency power supply 34.

In the embodiment illustrated in FIG. 20, the bias power supply 33 is electrically connected to the second electrode film 142 via the low-pass filter 33L. The low-pass filter 33L is connected between the bias power supply 33 and a node where two electric paths respectively connecting the radio-frequency power supply 34 and the bias power supply 33 to the second electrode film 142 merge with each other.

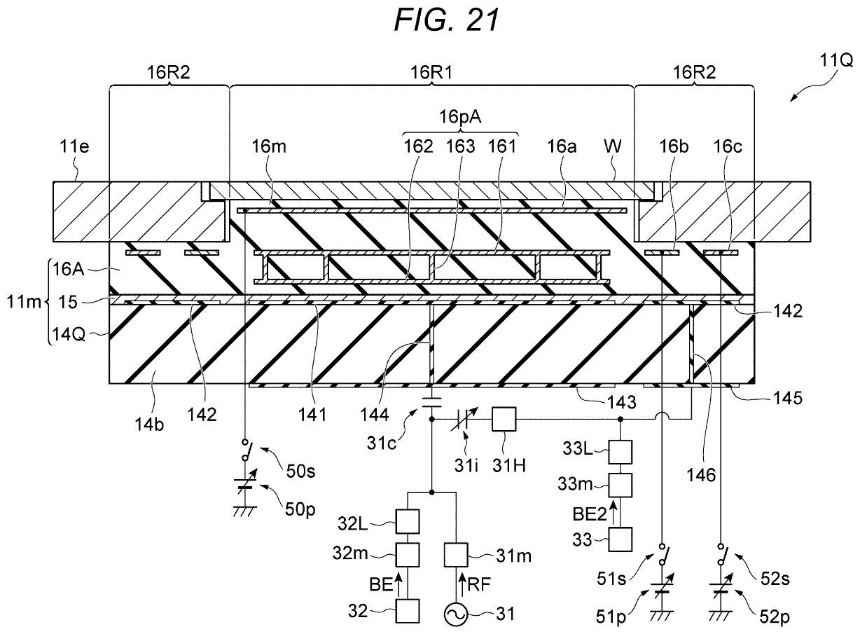

Hereinafter, FIG. 21 will be referred to. FIG. 21 is a diagram illustrating a substrate support according to still another exemplary embodiment. Hereinafter, differences between the embodiment illustrated in FIG. 21 and the embodiment illustrated in FIG. 20 will be described.

In the embodiment illustrated in FIG. 21, the radio-frequency power supply 34 is not used. In the embodiment illustrated in FIG. 21, the radio-frequency power supply 31 and the bias power supply 32 are electrically connected to the first electrode film 141 (or the electrode film 143). Further, the radio-frequency power supply 31 is electrically connected to the second electrode film 142 (or the electrode film 145). The radio-frequency power supply 31 is electrically connected to the second electrode film 142 via an impedance adjuster 31i and a high-pass filter 31H. Further, the radio-frequency power supply 31 and the bias power supply 32 are electrically connected to the first electrode film 141 via a capacitor 31c. The impedance adjuster 31i and the high-pass filter 31H are connected between the second electrode film 142 and a branch node where two electric paths respectively connecting the radio-frequency power supply 31 to the first electrode film 141 and the second electrode film 142 branch from each other. The capacitor 31c is electrically connected between the branch node and the first electrode film 141.

The high-pass filter 31H has a characteristic of blocking or attenuating the bias energy BE, and passing the radio-frequency power RF. The impedance adjuster 31i has a variable impedance. The impedance adjuster 31i may include, for example, a variable capacitor. A distribution ratio of the radio-frequency power RF between the first electrode film 141 and the second electrode film 142 is adjusted by adjusting the impedance of the impedance adjuster 31i.

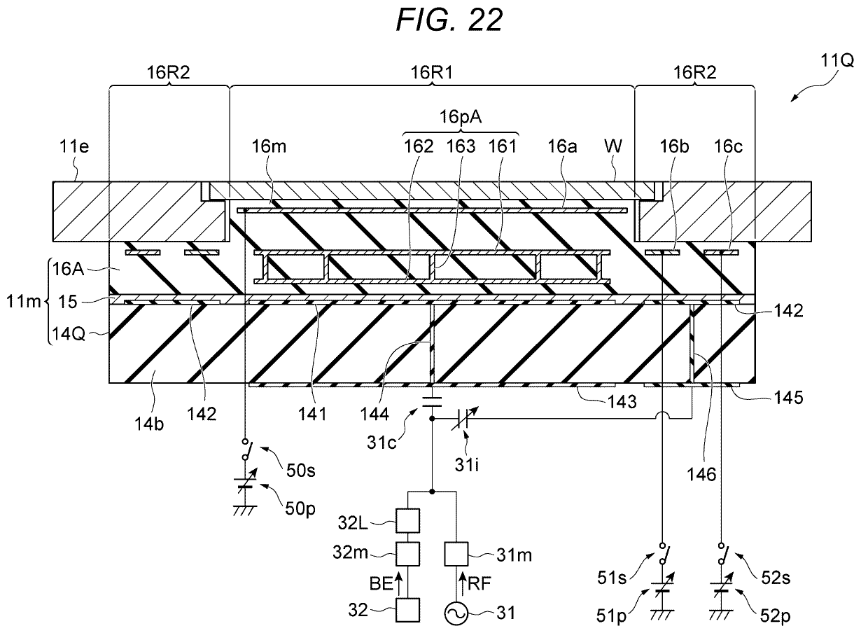

Hereinafter, FIG. 22 will be referred to. FIG. 22 is a diagram illustrating a substrate support according to still another exemplary embodiment. Hereinafter, differences between the embodiment illustrated in FIG. 22 and the embodiment illustrated in FIG. 21 will be described.

In the embodiment illustrated in FIG. 22, the bias power supply 33 and the high-pass filter 31H are not used. The radio-frequency power supply 31 and the bias power supply 32 each are electrically connected to the first electrode film 141 and the second electrode film 142. The impedance adjuster 31i is connected between a branch node and the second electrode film 142 (or the electrode film 145). The branch node is a node where an electric path electrically connecting the radio-frequency power supply 31 and the bias power supply 32 to the first electrode film 141 and an electric path electrically connecting the radio-frequency power supply 31 and the bias power supply 32 to the second electrode film 142 are branched from each other. In the embodiment illustrated in FIG. 22, a distribution ratio of each of the radio-frequency power RF and the bias energy BE between the first electrode film 141 and the second electrode film 142 is adjusted by adjusting the impedance of the impedance adjuster 31i.

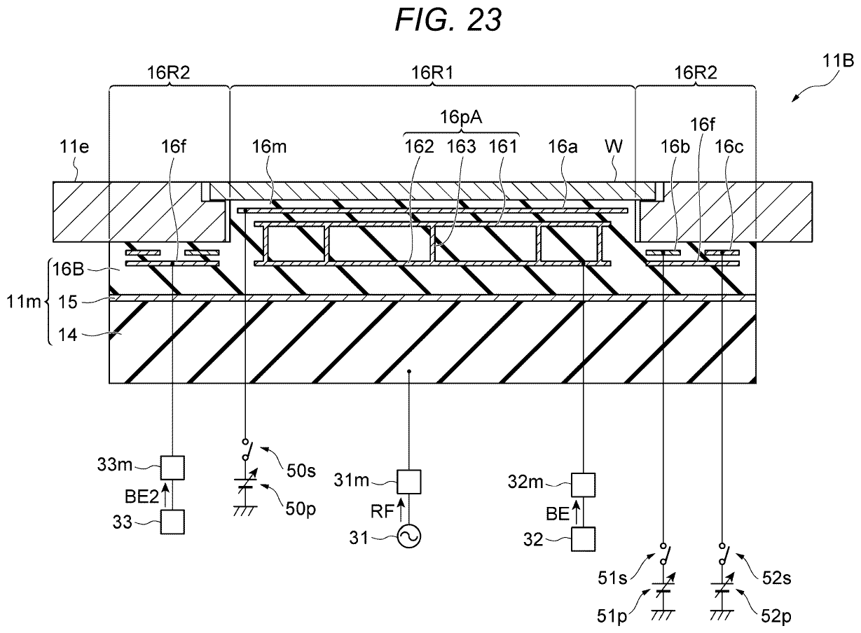

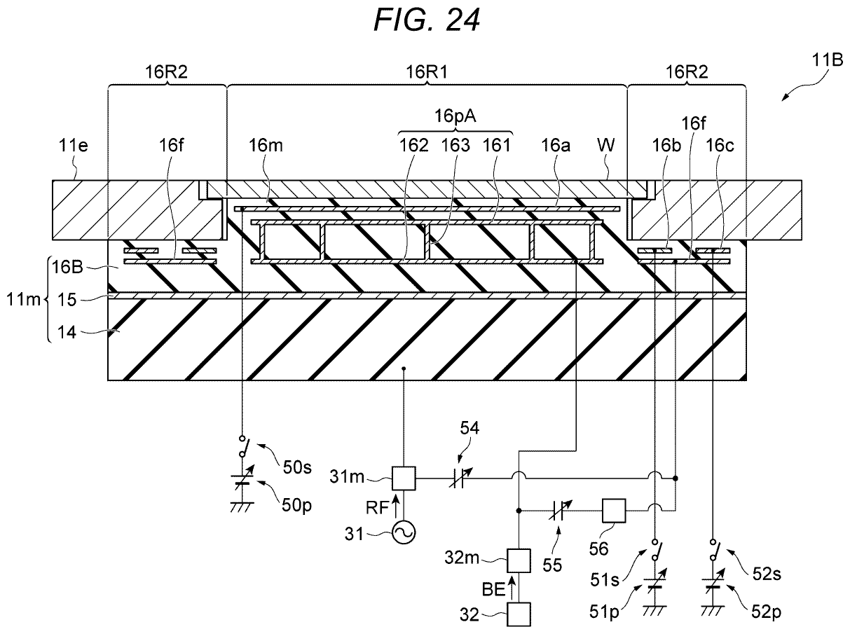

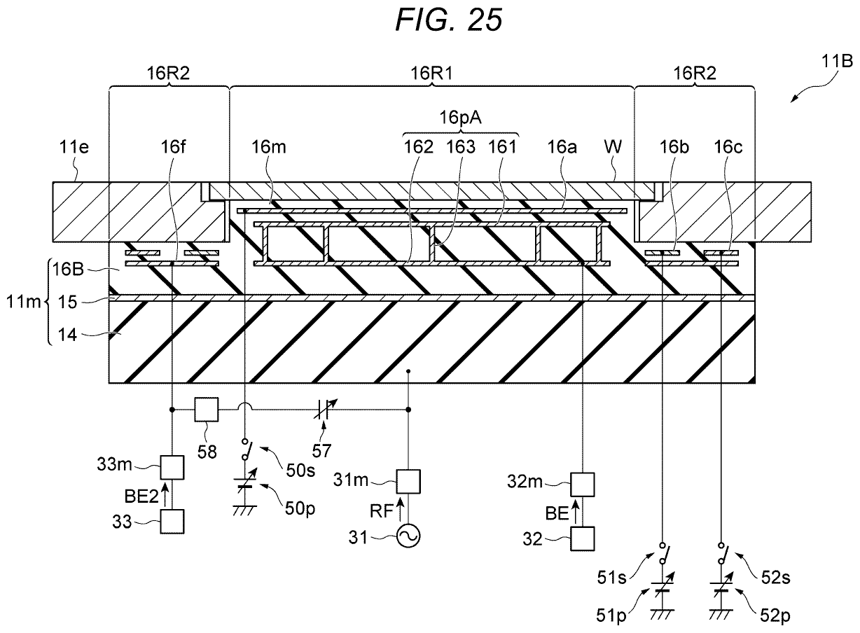

Hereinafter, FIGS. 23 to 25 will be referred to. Each of FIGS. 23 to 25 is a view illustrating a substrate support according to still another exemplary embodiment. Hereinafter, differences between the embodiment illustrated in FIG. 23 and the embodiment illustrated in FIG. 4 will be described. Further, differences between the embodiment illustrated in FIG. 24 and the embodiment illustrated in FIG. 5 will be described. Further, differences between the embodiment illustrated in FIG. 25 and the embodiment illustrated in FIG. 6 will be described.

In the embodiment illustrated in each of FIGS. 23 to 25, the bias electrode 16e is not provided in the electrostatic chuck. The part 16pA is provided below and in a vicinity of the chuck electrode 16a. The bias power supply 32 is electrically connected to the part 16pA. In the embodiment illustrated in each of FIGS. 23 to 25, the bias electrode 16e is not provided, and thus, a structure of the electrostatic chuck is simpler.

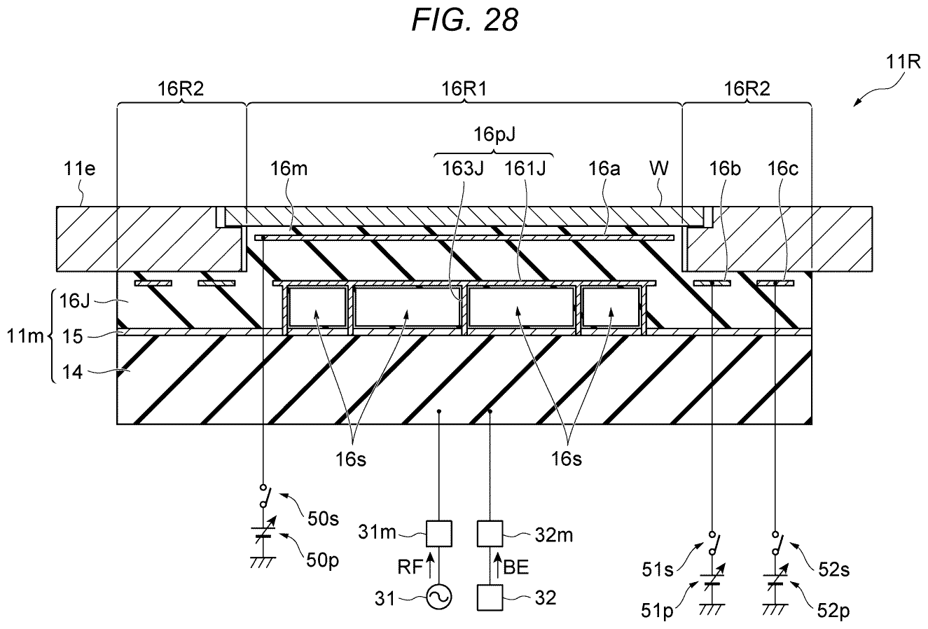

Hereinafter, FIG. 28 will be referred to. FIG. 28 is a diagram illustrating a substrate support according to still another exemplary embodiment. A substrate support 11R illustrated in FIG. 28 may be used as the substrate support 11 of the plasma processing apparatus 1. Hereinafter, the differences between the substrate support 11R and the substrate support 11J illustrated in FIG. 13 will be described.

In the substrate support 11R, a space 16s is formed in the main body 16m of the electrostatic chuck 16J. The space 16s is a continuous cavity. The space 16s may be formed between the electrode 161J and the lower surface of the main body 16m.

A heat transfer gas source may be connected to the space 16s. The heat transfer gas (e.g., a He gas) from a heat transfer gas source may be supplied to a back side of the substrate W via a supply port through the space 16s.

Alternatively, a heat medium (e.g., Galden®) may be supplied into the space 16s to adjust the temperature of the electrostatic chuck 16J. In this case, the heat medium is circulated between the heat medium supply device and the space 16s.

The electrostatic chucks of the substrate supports according to the various exemplary embodiments described above may be produced by a production method described below. In the production method, a plurality of green sheets constituting an electrostatic chuck are stacked later. Subsequently, the stacked green sheets are sintered. Accordingly, the electrostatic chuck can be produced.

While various exemplary embodiments have been described above, various additions, omissions, substitutions and changes may be made without being limited to the exemplary embodiments described above. Also, the other embodiments may be formed by combining elements in different embodiments.

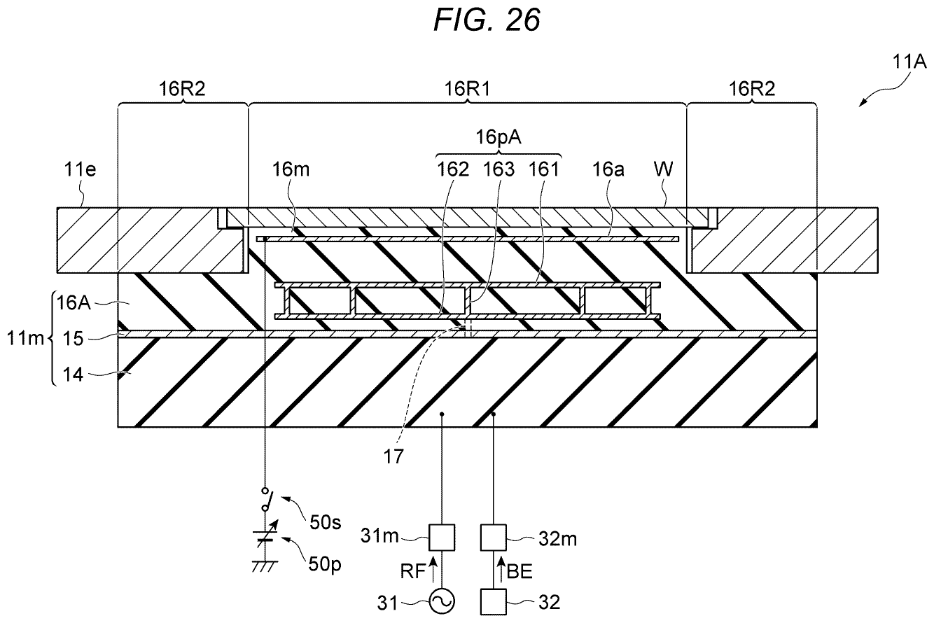

For example, as illustrated in FIG. 26, the second region 16R2 does not need to have the chuck electrodes 16b and 16c. Further, in the embodiments illustrated in FIGS. 3 to 8, any one of the parts 16pE, 16pF, 16pH, 16pJ, 16pK, 16pL, 16pM, and 16pN may be used instead of the part 16pA. Further, the base 14Q may be used instead of the bases of the substrate supports in various embodiments other than the substrate support 11Q.

Hereinafter, various exemplary embodiments included in the present disclosure will be described in [E1] to [E20].

### [E1]

A substrate support including:
a base, and
an electrostatic chuck disposed on the base, in which
the electrostatic chuck includes
   a first region configured to hold a substrate placed thereon,
   a second region extending to surround the first region and configured to support an edge ring placed thereon,
the first region has a thickness larger than a thickness of the second region, and
the electrostatic chuck has a part on at least one of the first region and the second region, the part being configured to reduce a difference between an electrostatic capacity per unit area of the first region between an upper surface of the first region and the base and an electrostatic capacity per unit area of the second region between an upper surface of the second region and the base.

In the electrostatic chuck having the part, the thickness of the first region is larger than the thickness of the second region. However, the difference between the electrostatic capacity per unit area of the first region and the electrostatic capacity per unit area of the second region is reduced. Therefore, in the substrate support, a difference between an impedance between the base and the substrate and an impedance between the base and the edge ring can be reduced.

### [E2]

The substrate support according to [E1], in which
the part is provided in the first region, and includes
   a first electrode,
   a second electrode extending below the first electrode, and
   an interconnector electrically connecting the first electrode and the second electrode to each other.

### [E3]

The substrate support according to [E2], in which
the first electrode is provided such that a distance between the first electrode and the upper surface of the first region decreases stepwise or gradually as a distance from a center of the first region in a radial direction increases.

### [E4]

The substrate support according to [E1], in which
the part includes a conductor plate provided in the first region.

### [E5]

The substrate support according to [E1] in which
the part is provided in the first region and is formed of a metal-based composite material.

### [E6]

The substrate support according to [E1], in which
the part is provided in the first region or constitutes the first region, and is formed of a material having a dielectric constant higher than a dielectric constant of a dielectric material forming the second region.

### [E7]

The substrate support according to [E1], in which
the part provides a cavity in the second region.

### [E8]

The substrate support according to any one of [E 1] to [E7], in which
the base is formed of metal.

### [E9]

The substrate support according to [E1], in which
the base includes an upper surface formed of metal,
the part is provided in the first region, and includes
   an electrode, and
   an interconnector electrically connecting the electrode and the upper surface of the base to each other.

### [E10]

The substrate support according to any one of [E1] to [E7], in which
the base includes
   a base part formed of an insulator,
   a first electrode film provided below the first region and on an upper surface of the base part, and
   a second electrode film provided below the second region and on the upper surface of the base part.

### [E11]

The substrate support according to any one of [E1] to [E10], in which
the electrostatic chuck further includes a bias electrode disposed therein.

### [E12]

The substrate support according to [E11], in which
the bias electrode is provided between the upper surface of the first region and the part in the first region.

### [E13]

The substrate support according to [E12], in which
the electrostatic chuck further includes another bias electrode located in the second region.

### [E14]

A plasma processing apparatus including:
a chamber,
the substrate support according to any one of [E1] to [E13] disposed in the chamber,
a radio-frequency power supply configured to generate radio-frequency power for generating a plasma from a gas in the chamber, and
a bias power supply configured to generate bias energy for drawing ions from the plasma toward the substrate support, in which
at least one of the radio-frequency power and the bias energy is supplied via the base.

### [E15]

The plasma processing apparatus according to [E14], in which
the substrate support is the substrate support according to [E8], and
at least one of the radio-frequency power supply and the bias power supply is electrically connected to the base of the substrate support.

### [E16]

The plasma processing apparatus according to [E15], in which
both the radio-frequency power supply and the bias power supply are electrically connected to the base.

### [E17]

The plasma processing apparatus according to [E14], in which
the substrate support is the substrate support according to [E10],
the radio-frequency power supply is electrically connected to the first electrode film and the second electrode film,
the bias power supply is electrically connected to the first electrode film, and
another bias power supply electrically connected to the second electrode film is further provided.

### [E18]

The plasma processing apparatus according to [E14], in which
the substrate support is the substrate support according to [E11] or [E12], and
the bias power supply is electrically connected to the bias electrode.

### [E19]

The plasma processing apparatus according to [E14], in which
the substrate support is the substrate support according to [E13],
the bias power supply is electrically connected to the bias electrode provided in the first region, and
the bias power supply or another bias power supply is electrically connected to the other bias electrode provided in the second region.

### [E20]

A method of producing an electrostatic chuck of the substrate support according to any one of [E1] to [E13], the method including:
stacking a plurality of green sheets, and
sintering the plurality of stacked green sheets.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

1. A plasma processing apparatus, comprising:
a plasma processing chamber;
a substrate support disposed in the plasma processing chamber, the substrate support including:
a base,
an electrostatic chuck disposed on the base and having a central region with a substrate support surface and an annular region surrounding the central region, the annular region having a thickness smaller than a thickness of the central region,
a chuck electrode disposed in the central region, and
an electrode structure disposed below the chuck electrode in the central region and being in an electrically floating state, the electrode structure including a first electrode layer, a second electrode layer disposed below the first electrode layer, and one or more connectors connecting the first electrode layer and the second electrode layer, the first electrode layer and the second electrode layer extending over the substrate support surface in a plan view; and
at least one bias power supply electrically connected to the substrate support.

2. The plasma processing apparatus according to claim 1, wherein the first electrode layer and the second electrode layer extend over the substrate support surface in the plan view.

3. The plasma processing apparatus according to claim 1, wherein the first electrode layer is disposed such that a distance between the first electrode layer and the substrate support surface decreases stepwise or gradually as a distance from a center of the central region in a radial direction increases.

4. The plasma processing apparatus according to claim 1, wherein the base includes
an insulator,
a first electrode film disposed below the central region and on the insulator, and
a second electrode film disposed below the annular region and on the insulator.

5. The plasma processing apparatus according to claim 4, wherein
the at least one bias power supply includes a first bias power supply and a second bias power supply,
the first bias power supply is electrically connected to the first electrode film, and
the second bias power supply is electrically connected to the second electrode film.

6. The plasma processing apparatus according to claim 1, further comprising a bias electrode which is disposed in the central region and extends over the substrate support surface in the plan view.

7. The plasma processing apparatus according to claim 6, wherein the bias electrode is disposed between the chuck electrode and the electrode structure.

8. The plasma processing apparatus according to claim 7, wherein the at least one bias power supply is electrically connected to the bias electrode.

9. The plasma processing apparatus according to claim 6, further comprising another bias electrode disposed in the annular region.

10. The plasma processing apparatus according to claim 9, wherein the at least one bias power supply is electrically connected to the bias electrode and the other bias electrode.

11. The plasma processing apparatus according to claim 9, wherein
the at least one bias power supply includes a first bias power supply and a second bias power supply,
the first bias power supply is electrically connected to the bias electrode, and
the second bias power supply is electrically connected to the other bias electrode.

12. The plasma processing apparatus according to claim 1, wherein the base is formed of metal.

13. The plasma processing apparatus according to claim 12, further comprising an RF power supply, wherein
both the RF power supply and the bias power supply are electrically connected to the base.

14. A substrate support, comprising:
an electrostatic chuck having a central region with a substrate support surface and an annular region surrounding the central region, the annular region having a thickness smaller than a thickness of the central region:
a chuck electrode disposed in the central region; and
an electrode structure disposed below the chuck electrode in the central region and being in an electrically floating state, the electrode structure including a first electrode layer, a second electrode layer disposed below the first electrode layer, and one or more connectors connecting the first electrode layer and the second electrode layer, the first electrode layer and the second electrode layer extending over the substrate support surface in a plan view.

15. A plasma processing apparatus, comprising:
a plasma processing chamber;
a substrate support disposed in the plasma processing chamber, the substrate support including
a base,
an electrostatic chuck disposed on the base and having a central region with a substrate support surface and an annular region surrounding the central region, the annular region having a thickness smaller than a thickness of the central region,
a chuck electrode disposed in the central region, and
an electrode structure disposed below the chuck electrode in the central region, the electrode structure including a first electrode layer extending over the substrate support surface in a plan view; and
at least one power supply electrically connected to the electrode structure.

16. The plasma processing apparatus according to claim 15, wherein
the electrode structure further includes
a second electrode layer disposed below the first electrode layer and extending over the substrate support surface in the plan view,
one or more connectors connecting the first electrode layer and the second electrode layer, and
a conductor connecting the second electrode layer and the base, and
the at least one power supply is electrically connected to the electrode structure via the conductor.

17. The plasma processing apparatus according to claim 15, wherein
the electrode structure further includes one or more connectors connecting the first electrode layer and the base, and
the at least one power supply is electrically connected to the electrode structure via the one or more connectors.

18. A substrate support, comprising:
a base;
an electrostatic chuck having a central region and an annular region surrounding the central region, the central region having a substrate support surface, the annular region having an edge ring support surface, the annular region having a thickness smaller than a thickness of the central region;
a chuck electrode disposed in the central region; and
an element disposed below the chuck electrode in the central region and configured to reduce a difference between an electrostatic capacity per unit area of the central region between the substrate support surface and the base and an electrostatic capacity per unit area of the annular region between the edge ring support surface and the base.

19. The substrate support according to claim 18, wherein the element includes a conductor plate.

20. The substrate support according to claim 18, wherein the element is formed of a metal-based composite material.

21. The substrate support according to claim 18, wherein the element is formed of a material having a dielectric constant higher than a dielectric constant of a dielectric material forming the annular region.
